(19) United States
(12) Patent Application Publication
(10) Pub. No.: US 2025/0172873 A1
(43) Pub. Date: May 29, 2025

(54) PHOTOSENSITIVE RESIN COMPOSITION, CURED ARTICLE, METHOD FOR MANUFACTURING CURED ARTICLE, ORGANIC EL DISPLAY DEVICE, AND DISPLAY DEVICE

(71) Applicant: TORAY Industries, Inc., Tokyo (JP)

(72) Inventors: Yusuke KOMORI, Otsu-shi (JP); Hiroki NISHIOKA, Otsu-shi (JP)

(73) Assignee: TORAY Industries, Inc., Tokyo (JP)

(21) Appl. No.: 18/843,415

(22) PCT Filed: Feb. 16, 2023
(86) PCT No.: PCT/JP2023/005379

§ 371 Date: Sep. 3, 2024

(30) Foreign Application Priority Data
Mar. 11, 2022 (JP) 2022-037755
Aug. 23, 2022 (JP) 2022-132335

(51) Int. Cl. G03F 7/039; C08G 73/12; C08K 5/138; C08K 5/3492; G03F 7/00; G03F 7/004; G03F 7/09; H10K 59/124; H10K 59/131; H10K 59/80

(52) U.S. Cl. CPC G03F 7/0392; C08G 73/12; C08K 5/138; C08K 5/3492; G03F 7/0007; G03F 7/0045; G03F 7/094; H10K 59/124; H10K 59/131; H10K 59/8791

(57) ABSTRACT

The present invention relates to a photosensitive resin composition that has high sensitivity, and can form a film having low transmittance after curing regardless of the heating atmosphere during curing. The photosensitive resin composition of the present invention contains an alkali-soluble resin (a); an aromatic hydrocarbon (b) having at least one aromatic C—H bond and at least three phenolic hydroxyl groups in one aromatic ring; a thermal cross-linking agent (c) having a partial structure represented by the formula (1); and a photosensitive compound (e). In the formula (1), R¹⁰ represents a hydrogen atom or an alkyl group, each * represents a bond, and a carbonyl group is not adjacent to a nitrogen atom.

### TECHNICAL FIELD

The present invention relates to a photosensitive resin composition that can be suitably used for a planarization layer, an insulating layer, and the like of an organic EL display device.

### BACKGROUND ART

Organic electroluminescence (hereinafter referred to as organic EL) display device has been used in display devices having a thin display, such as smartphones, tablet personal computers, and televisions, to develop many products. In general, an organic EL display device has a drive circuit, a planarization layer, a first electrode, an insulating layer, a light-emitting layer, and a second electrode that are placed over a substrate. The organic EL display device can emit light when a voltage is applied between the first electrode and the second electrode facing to each other. As a material for a planarization layer or an insulating layer among the above-described components, photosensitive resin compositions that can be patterned by ultraviolet irradiation are generally used. Among the photosensitive resin compositions, photosensitive resin compositions in which a polyimide-based resin is used have high heat resistance of the resin and a small amount of gas components generated from the cured article, and therefore are suitably used from the viewpoint of obtaining a highly reliable organic EL display device.

In recent years, along with the application of a driving thin film transistor (Thin Film Transistor: hereinafter, referred to as a TFT) using an oxide semiconductor layer to an organic EL display device, it is required to lower the transmittance of ultraviolet light of an insulating layer and a planarization layer in order to prevent malfunction and the like due to entry of light into the TFT. In addition, for the purpose of improving light extraction efficiency of an organic EL display device, thinning of a polarizing plate and a display device without a polarizing plate have been developed, and in order to improve contrast, it is required to lower the transmittance of visible light of an insulating layer and a planarization layer.

As a technique for reducing the transmittance of ultraviolet light in the cured article, there is a method of adding dihydroxynaphthalene and a thermal cross-linking agent having a specific structure to an alkali-soluble resin containing polyimide and/or a polyimide precursor (refer to Patent Document 1). Examples of the technique of decreasing the transmittance of visible light in a cured article and increasing the blackness include a method of adding a colorant such as carbon black, an organic/inorganic pigment, or a dye to a resin composition as can be seen in black matrix materials for liquid crystal display devices and RGB paste materials. Examples thereof include a method of adding a quinone diazide compound esterified and at least one colorant selected from a dye, an inorganic pigment, and an organic pigment to an alkali-soluble heat-resistant resin (refer to Patent Document 2), and a method of adding a photosensitizer and yellow, red, and blue dyes and/or pigments to an alkali-soluble resin made of a polyimide and/or a polyimide precursor (refer to Patent Document 3).

However, the resin composition prepared by the method described in Patent Document 1 does not have a sufficient ultraviolet light shielding property, and the resin compositions prepared by the methods described in Patent Documents 2 and 3 contain a coloring material having absorption in an exposure wavelength region of 350 nm to 450 nm of a mercury lamp generally used as an exposure light source, and thus have a problem of deteriorating exposure sensitivity.

On the other hand, as a technique for reducing the transmittance of ultraviolet light in the cured article, there is a method of adding a novolac resin, a photosensitizer, and a polymer other than the novolac resin (refer to Patent Document 4), and as a technique for reducing the transmittance of visible light and increasing the blackness, there is a method of adding, to an alkali-soluble resin, a quinone diazide compound, a thermally color-developing compound that develops color by heating and exhibits an absorption maximum at 350 nm or more and 700 nm or less, and a compound that does not have an absorption maximum at 350 nm or more and less than 500 nm and has an absorption maximum at 500 nm or more and 750 nm or less (refer to Patent Document 5).

### PRIOR ART DOCUMENTS

### Patent Documents

Patent Document 1: International Publication No. 2010/087238
Patent Document 2: Japanese Patent Laid-open Publication No. 2004-145320
Patent Document 3: Japanese Patent Laid-open Publication No. 2018-63433
Patent Document 4: International Publication No. 2015/129092
Patent Document 5: Japanese Patent Laid-open Publication No. 2004-326094

### SUMMARY OF THE INVENTION

### Problems to be Solved by the Invention

As a result of examination by the applicant, the resin compositions of Patent Documents 4 and 5 which are heated decrease the transmittance by utilizing oxidation by oxygen in the air during thermal curing, and thus the transmittance does not decrease under an inert gas atmosphere, and there are restrictions on curing conditions.

### Solutions to the Problems

In order to solve the above-mentioned problems, the photosensitive resin composition of the present invention has the following constitution.

[1] A photosensitive resin composition containing: an alkali-soluble resin (a); an aromatic hydrocarbon (b) having at least one aromatic C—H bond and at least three phenolic hydroxyl groups in one aromatic ring; a thermal cross-linking agent (c) having a partial structure represented by a formula (1); and a photosensitive compound (e),

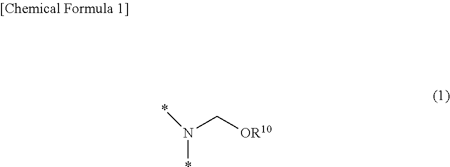

where R¹⁰ represents a hydrogen atom or an alkyl group, each * represents a bond, and a carbonyl group is not adjacent to a nitrogen atom.

[2] The photosensitive resin composition according to [1], wherein the component (c) includes two or more partial structures represented by the formula (1) in a molecule.

[3] The photosensitive resin composition according to [1] or [2], wherein the component (c) contains a triazine ring-containing compound (c1) represented by a formula (2):

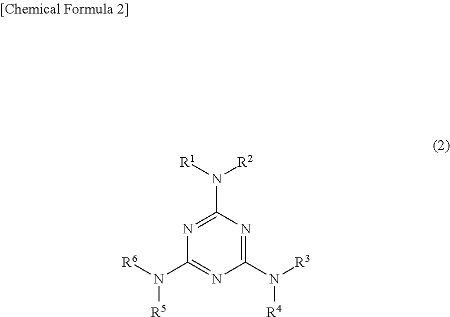

where R¹ to R⁶ each independently represent a hydrogen atom, an alkyl group having 1 to 10 carbon atoms, an alkenyl group having 2 to 10 carbon atoms, an alkenyl ether group having 2 to 10 carbon atoms, a methylol group, or an alkoxymethyl group, and at least one of R¹ to R⁶ is a methylol group or an alkoxymethyl group.

[4] The photosensitive resin composition according to any one of [1] to [3], further containing a colorant (d) having a maximum absorption wavelength in any of a range of 490 nm or more and less than 800 nm at 300 to 800 nm, and having 0.1% or more and less than 60% of a ratio of absorbance Abs₃₆₅ at 365 nm to absorbance Absₘₐₓ at the maximum absorption wavelength in any of the range of 490 nm or more and less than 800 nm at 300 to 800 nm.

[5] The photosensitive resin composition according to [4], wherein the component (d) contains a colorant (d-1) having a maximum absorption wavelength in any of a range of 490 nm or more and less than 580 nm at 300 to 800 nm and/or a colorant (d-2) having a maximum absorption wavelength in any of a range of 580 nm or more and less than 800 nm at 300 to 800 nm.

[6] The photosensitive resin composition according to [4], wherein the component (d) contains a dye (d1-1) having a maximum absorption wavelength in any of a range of 490 nm or more and less than 580 nm at 300 to 800 nm and/or a dye (d1-2) having a maximum absorption wavelength in any of a range of 580 nm or more and less than 800 nm at 300 to 800 nm.

[7] The photosensitive resin composition according to [4] or [6], wherein the component (d) contains an ionic dye forming an ion pair of an organic anion moiety and an organic cation moiety, and the organic anion moiety and the organic cation moiety is made of an organic anion moiety of an acidic dye and an organic cation moiety of a basic dye, respectively.

[8] The photosensitive resin composition according to any one of [4] to [7], including, as the component (d), n types of ionic dyes forming an ion pair of an organic anion moiety and an organic cation moiety, wherein organic ions contained in the photosensitive resin composition are of (n+1) types, and
n represents an integer of 2 to 10.

[9] The photosensitive resin composition according to any one of [1] to [8], wherein in the component (b), with respect to any of the phenolic hydroxyl groups, at least one substitution position of other phenolic hydroxyl groups is an ortho position or a para position.

[10] The photosensitive resin composition according to any one of [1] to [9], wherein a content of the component (b) is 1 to 50 parts by mass with respect to 100 parts by mass of the component (a).

[11] The photosensitive resin composition according to any one of [1] to [10], wherein a content of the component (c) is 1 to 100 parts by mass with respect to 100 parts by mass of the component (a).

[12] The photosensitive resin composition according to any one of [1] to [11], wherein the component (a) contains one or more types selected from the group consisting of a polyimide, a polyimide precursor, a polybenzoxazole, a polybenzoxazole precursor, a polyamideimide, a polyamideimide precursor, and a copolymer thereof.

[13] The photosensitive resin composition according to any one of [1] to [12], wherein a total mass of all chlorine atoms and all bromine atoms contained in the photosensitive resin composition is 150 ppm or less with respect to a total mass of solid content obtained by removing a solvent from the photosensitive resin composition.

[14] A cured article obtained by curing the photosensitive resin composition according to any one of [1] to [13].

[15] A method for producing a cured article, including the steps of: forming a resin film made of the photosensitive resin composition according to any one of [1] to [13] on a substrate; exposing the resin film; developing the exposed resin film; and subjecting the developed resin film to heat treatment.

[16] An organic electroluminescence (EL) display device including: a drive circuit; a planarization layer; a first electrode; an insulating layer; a light-emitting layer; and a second electrode that are placed over a substrate, wherein the planarization layer and/or the insulating layer includes the cured article according to [14].

[17] The organic EL display device according to [16], wherein the planarization layer and/or the insulating layer includes the cured article, and a transmittance of the planarization layer and/or the insulating layer at a wavelength of 450 nm is less than 30%.

[18] The organic EL display device according to [16] or [17], wherein the planarization layer and/or the insulating layer includes the cured article, and an OD value of the planarization layer and/or the insulating layer per 1 μm of film thickness in visible light is 0.5 to 1.5.

[19] The organic EL display device according to any one of [15] to [18], further including a color filter having a black matrix.

[20] A display device including: at least a metal wiring; the cured article according to [14]; and a plurality of luminescent elements, wherein each of the luminescent elements includes a pair of electrode terminals on either one surface, the pair of electrode terminals are connected to a plurality of the metal wirings extending in the cured article, and the plurality of the metal wirings are configured to retain electrical insulation properties by the cured article.

[21] A cured article containing a crosslinked body of 1,2,4-trihydroxybenzene or pyrogallol and a thermal cross-linking agent (c) having a partial structure represented by a formula (1):

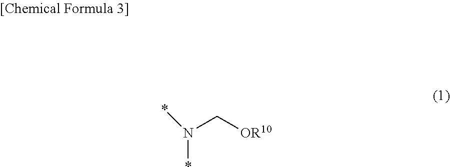

where R¹⁰ represents a hydrogen atom or an alkyl group, each * represents a bond, and a carbonyl group is not adjacent to a nitrogen atom.

[22] A cured article formed on a support, wherein the cured article has a normalized secondary ion intensity of ¹³⁷C₇H₅O₃⁻ of 1.0×10⁻⁴ or more as measured by time-of-flight secondary ion mass spectrometry under measurement conditions that cutting is performed by an Ar gas cluster ion beam method in a direction from a surface of the cured article toward the support, a primary ion species is Bi₃⁺⁺, a primary ion current is 0.1 pA, and an irradiation region of the primary ion is a region inside a quadrangle having a side length of 200 μm.

### Effects of the Invention

The photosensitive resin composition of the present invention has high sensitivity, and can form a film having low transmittance after curing regardless of the heating atmosphere during curing.

### BRIEF DESCRIPTION OF THE DRAWINGS

FIG. 1 is a cross-sectional view of an example of an organic EL display device.

FIG. 2 is a cross-sectional view of an example of a display device.

### EMBODIMENTS OF THE INVENTION

An embodiment of the present invention will be described in detail.

The photosensitive resin composition of the present invention contains an alkali-soluble resin (a); an aromatic hydrocarbon (b) having at least one aromatic C—H bond and at least three phenolic hydroxyl groups in one aromatic ring; a thermal cross-linking agent (c) having a partial structure represented by the formula (1); and a photosensitive compound (e),

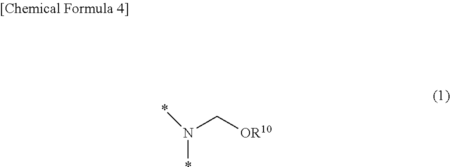

where R¹⁰ represents a hydrogen atom or an alkyl group, each * represents a bond, and a carbonyl group is not adjacent to a nitrogen atom.
   <Alkali-Soluble Resin (a)>

The photosensitive resin composition of the present invention contains an alkali-soluble resin (a) (hereinafter, may be referred to as a component (a)). The alkali solubility refers to allowing the dissolution rate determined from a reduction in film thickness in the case of applying a solution of the resin dissolved in γ-butyrolactone onto a silicon wafer, forming a prebaked film of 10 μm±0.5 μm in film thickness by pre-baking for 4 minutes at 120° C., immersing the prebaked film in a 2.38 mass % tetramethylammonium hydroxide aqueous solution at 23±1° C. for 1 minute, and then subjecting the film to a rinse treatment with pure water, to be 50 nm/minute or more.

The component (a) has alkali solubility, and thus has a hydroxyl group and/or an acidic group in the structural unit of the resin and/or at the main chain terminal thereof. Examples of the acidic group include a carboxy group, a phenolic hydroxyl group, and a sulfonic acid group.

As the component (a), known components such as polyimide, a polyimide precursor, polybenzoxazole, a polybenzoxazole precursor, polyamideimide, a polyamideimide precursor, polyamide, a polymer of a radically polymerizable monomer having an acidic group, a siloxane resin, a cardo resin, and a phenol resin are contained, but are not limited thereto. The photosensitive resin composition of the present invention may contain two or more types of these resins.

Among these components (a), the component (a) preferably includes one or more types selected from the group consisting of a polyimide, a polyimide precursor, a polybenzoxazole, a polybenzoxazole precursor, a polyamideimide, a polyamideimide precursor, and a copolymer thereof, and more preferably includes a polyimide, a polyimide precursor, a polybenzoxazole precursor, or a copolymer thereof, because of high development adhesion, excellent heat resistance, and high long-term reliability when a cured article is used for an organic EL display device due to a small amount of outgas at a high temperature. Further, from the viewpoint of further improving the sensitivity, the component (a) more preferably includes a polyimide precursor or a polybenzoxazole precursor. Herein, the polyimide precursor refers to a resin which is converted into polyimide by a heat treatment or a chemical treatment, and examples thereof include polyamic acid and a polyamic acid ester. The polybenzoxazole precursor refers to a resin which is converted into polybenzoxazole by a heat treatment or a chemical treatment, and examples thereof include polyhydroxyamide.

The polyimide precursor and the polybenzoxazole precursor describe above have a structural unit represented by the following formula (3), and the polyimide has a structural unit represented by the following formula (4). Two or more types of these may be contained, or a resin obtained by copolymerizing the structural unit represented by the formula (3) and the structural unit represented by the formula (4) may be contained.

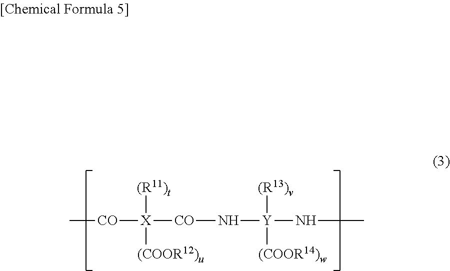

In the formula (3), X represents a divalent to octavalent organic group having 4 to 40 carbon atoms, and Y represents a divalent to undecavalent organic group having 6 to 40 carbon atoms. R¹¹ and R¹³ each independently represent a hydroxyl group or a sulfonic acid group. R¹² and R¹⁴ each independently represent a hydrogen atom or a monovalent hydrocarbon group having 1 to 20 carbon atoms. t, u, and w represent an integer of 0 to 3 and v represents an integer of 0 to 6. However, when the structural unit represented by the formula (3) represents a structural unit of a polyimide precursor, u≥2, and when the structural unit represented by the formula (3) represents a structural unit of a polybenzoxazole precursor, v≥2, and at least two of the plurality of R¹³s are hydroxyl groups.

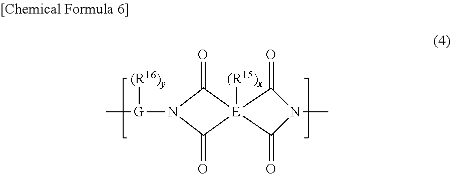

In the formula (4), E represents a tetravalent to decavalent organic group having 4 to 40 carbon atoms, and G represents a divalent to octavalent organic group having 6 to 40 carbon atoms. R¹⁵ and R¹⁶ each independently represent a carboxy group, a sulfonic acid group, or a hydroxyl group. x and y each independently represent an integer of 0 to 6. Provided that, x+y>0.

It is preferable that the polyimide, the polyimide precursor, the polybenzoxazole precursor, or a copolymer thereof has 5 to 100,000 of structural units represented by the formula (3) or (4). In addition to the structural unit represented by the formula (3) or (4), another structural unit may be contained. In this case, 50 mol % or more of the structural units represented by the formula (3) or (4) per 100 mol % of the whole structural units is preferably contained.

In the formula (3), X(R¹¹)ₜ(COOR¹²)ᵤ represents a residue of an acid. X is a divalent to octavalent organic group having 4 to 40 carbon atoms, and preferably a divalent to octavalent organic group containing an aromatic ring or a cyclic aliphatic group.

Examples of the residue of the acid may include residues of dicarboxylic acids such as terephthalic acid, isophthalic acid, diphenyl ether dicarboxylic acid, bis(carboxyphenyl)hexafluoropropane, biphenyldicarboxylic acid, benzophenonedicarboxylic acid, and triphenyldicarboxylic acid, residues of tricarboxylic acids such as trimellitic acid, trimesic acid, diphenyl ether tricarboxylic acid, and biphenyltricarboxylic acid, and residues of tetracarboxylic acids such as aromatic tetracarboxylic acids such as pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl) ether, 1,2,5,6-naphthalenetetracarboxylic acid, 2,3,6,7-naphthalenetetracarboxylic acid, 2,3,5,6-pyridinetetracarboxylic acid, 3,4,9,10-perylenetetracarboxylic acid, aromatic tetracarboxylic acids having the structures presented below, aliphatic tetracarboxylic acids such as butanetetracarboxylic acid, and aliphatic tetracarboxylic acids having a cyclic aliphatic group such as 1,2,3,4-cyclopentanetetracarboxylic acid. X(R¹¹)ₜ(COOR¹²)ₙ may have two or more types of these residues.

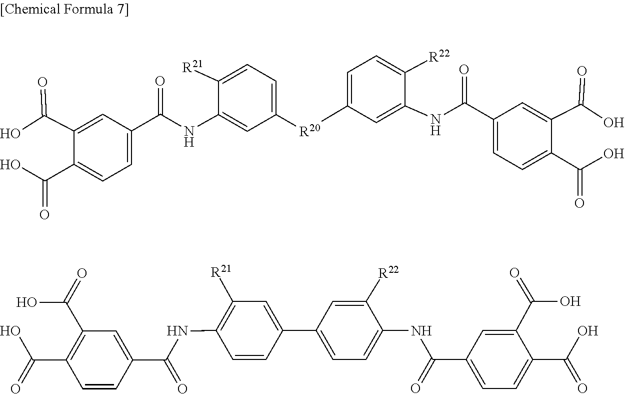

R²⁰ represents an oxygen atom, C(CF₃)₂, or C(CH₃)₂. R²¹ and R²² each independently represent a hydrogen atom or a hydroxyl group.

Among the residues of the acid, one or two carboxy groups correspond to (COOR¹²) in the formula (1) in the case of a residue of tricarboxylic acid or a tetracarboxylic acid.

In the above formula (4), E(R¹⁵)ₓ represents of a residue of a dianhydride. E is a tetravalent to decavalent organic group having 4 to 40 carbon atoms, and preferably an organic group containing an aromatic ring or a cyclic aliphatic group.

Specific examples of the residue of the dianhydride include residues of aromatic tetracarboxylic dianhydrides such as pyromellitic dianhydride, 3,3′,4,4′-biphenyltetracarboxylic dianhydride, 2,3,3′,4′-biphenyltetracarboxylic dianhydride, 2,2′,3,3′-biphenyltetracarboxylic dianhydride, 3,3′,4,4′-benzophenone tetracarboxylic dianhydride, 2,2′,3,3′-benzophenone tetracarboxylic dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl)ether dianhydride, 1,2,5,6-naphthalenetetracarboxylic dianhydride, 9,9-bis(3,4-dicarboxyphenyl)fluorenic dianhydride, 9,9-bis{4-(3,4-dicarboxyphenoxy)phenyl}fluorenic dianhydride, 2,3,6,7-naphthalenetetracarboxylic dianhydride, 2,3,5,6-pyridinetetracarboxylic dianhydride, 3,4,9,10-perylenetetracarboxylic dianhydride, 2,2-bis(3,4-dicarboxyphenyl)hexafluoropropane dianhydride, and dianhydrides having the structures presented below, aliphatic tetracarboxylic dianhydrides such as butanetetracarboxylic dianhydride, and aliphatic tetracarboxylic dianhydrides containing a cyclic aliphatic group, such as 1,2,3,4-cyclopentanetetracarboxylic dianhydride. E(R¹⁵)ₓ may have two or more types of these residues.

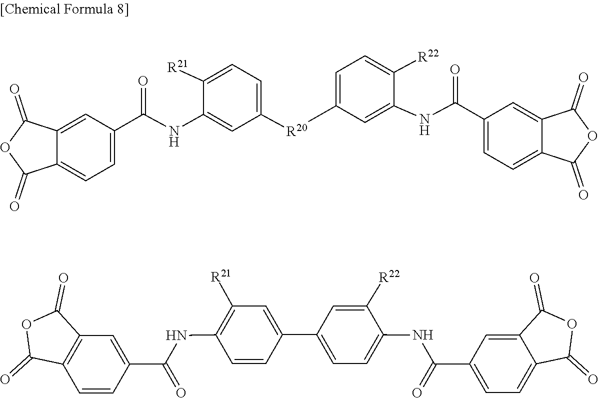

R²⁰ represents an oxygen atom, C(CF₃)₂, or C(CH₃)₂. R²¹ and R²² each independently represent a hydrogen atom or a hydroxyl group.

Y(R¹³)ᵥ(COOR¹⁴)_{w} in the above formula (3) and G (R¹⁶)_{y} in the above formula (4) each represent a residue of a diamine. Y is a divalent to undecavalent organic group having 6 to 40 carbon atoms, and preferably a divalent to undecavalent organic group containing an aromatic ring or a cyclic aliphatic group. G is a divalent to octavalent organic group having 6 to 40 carbon atoms, and preferably a divalent to octavalent organic group containing an aromatic ring or a cyclic aliphatic group.

Specific examples of the residue of the diamine can include residues of 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis{4-(4-aminophenoxy)phenyl}ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, 9,9-bis(4-aminophenyl)fluorene, 2,2′-bis(trifluoromethyl)-5,5′-dihydroxybenzidine, 3,5-diaminobenzoic acid, 3,4-diaminobenzoic acid, 2,5-diaminobenzoic acid, residues of aromatic diamines such as compounds obtained by substituting at least some of the hydrogen atoms of aromatic rings of these with an alkyl group or a halogen atom, residues of aliphatic diamines having a cyclic aliphatic group such as cyclohexyldiamine and methylenebiscyclohexylamine, and residues of diamines having the structures presented below. Y(R¹³)ᵥ(COOR¹⁴)_{w} and G(R¹⁶)_{y} may have two or more types of these residues.

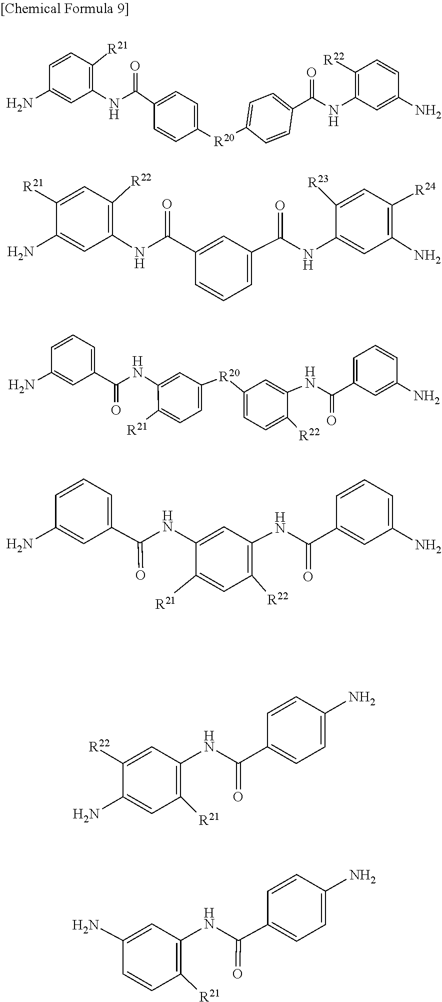

R²⁰ represents an oxygen atom, C(CF₃)₂, or C(CH₃)₂. R²¹ to R²⁴ each independently represent a hydrogen atom or a hydroxyl group.

The terminal of these resins may be sealed with a monoamine, an acid anhydride, an acid chloride, a monocarboxylic acid, and an active ester compound, which have a known acidic group.

The component (a) may be synthesized by a known method.

Examples of the method for producing a polyamic acid as a polyimide precursor include a method in which tetracarboxylic dianhydride and a diamine compound are reacted in a solvent at a low temperature.

Examples of the method for producing a polyamic acid ester as a polyimide precursor like a polyamic acid include, in addition to the above-described method in which a polyamic acid is reacted with an esterifying agent, a method in which a diester is obtained from tetracarboxylic dianhydride and an alcohol, and then the diester is reacted with an amine in a solvent in the presence of a condensing agent, and a method in which a diester is obtained from tetracarboxylic dianhydride and an alcohol, then the remaining dicarboxylic acid is converted into an acid chloride, and the acid chloride is reacted with an amine in a solvent. From the viewpoint of ease of synthesis, a step of reacting a polyamic acid with an esterifying agent is preferably included. The esterifying agent is not particularly limited, and a known method can be applied, but N,N-dimethylformamide dialkyl acetal is preferable because the obtained resin is easily purified.

Examples of a method for producing polyhydroxyamide which is polybenzoxazole precursor include a method in which a bisaminophenol compound and a dicarboxylic acid are subjected to a condensation reaction in a solvent. Specific examples thereof include a method in which a dehydration condensing agent such as dicyclohexylcarbodiimide (DCC) is reacted with an acid, and a bisaminophenol compound is added thereto, and a method in which a solution of dicarboxylic acid dichloride is added dropwise to a solution of a bisaminophenol compound to which a tertiary amine such as pyridine is added.

Examples of a method for producing polyimide include a method in which the polyamic acid or polyamic acid ester obtained by the above-described method is subjected to dehydration cyclization in a solvent. Examples of a method of dehydration cyclization include a chemical treatment using an acid, a base and the like and heat treatment.

Examples of a method for producing polybenzoxazole include a method in which the polyhydroxyamide obtained by the above-described method is subjected to dehydration cyclization in a solvent. Examples of a method of dehydration cyclization include a chemical treatment using an acid, a base and the like and heat treatment.

Examples of the polyamide-imide precursor include polymers of a tricarboxylic acid, a corresponding tricarboxylic anhydride, and a tricarboxylic anhydride halide with a diamine compound, and a polymer of trimellitic anhydride chloride with an aromatic diamine compound is preferable. Examples of a method for producing the polyamide-imide precursor include a method in which a tricarboxylic acid, a corresponding tricarboxylic anhydride, a tricarboxylic anhydride halide, or the like is reacted with a diamine compound at a low temperature in a solvent.

Examples of a method for producing the polyamide-imide include a method in which trimellitic anhydride is reacted with an aromatic diisocyanate in a solvent and a method in which the polyamide-imide precursor obtained by the above-described method is subjected to dehydration cyclization in a solvent. Examples of a method of dehydration cyclization include a chemical treatment using an acid, a base and the like and heat treatment.

Examples of the polymer of the radically polymerizable monomer having an acidic group include an acrylic resin and a polyhydroxystyrene resin. As the radically polymerizable monomer having an acidic group, known materials can be used, and examples thereof include o-hydroxystyrene, m-hydroxystyrene, and p-hydroxystyrene, and alkyl, alkoxy-substituted products, methacrylic acid, and acrylic acid thereof, and haloalkyl, alkoxy, halogen, nitro, and cyano substituted products thereof at the α-position. Among them, o-hydroxystyrene, m-hydroxystyrene, and p-hydroxystyrene, and alkyl and alkoxy-substituted products thereof are preferably used from the viewpoint of sensitivity and resolution at the time of patterning, residual film rate after development, heat deformation resistance, solvent resistance, adhesion to a base, storage stability of a solution, and the like. These can be used singly or in combination of two or more types thereof.

As the other radically polymerizable monomer having an acidic group, a known material can be used, and examples thereof include: styrene; an alkyl, alkoxy, halogen, haloalkyl, nitro, cyano, amide, and ester substituent at the α-, o-, m-, or p-position of styrene; diolefins such as butadiene and isoprene; and an esterified product of methacrylic acid or acrylic acid. These can be used singly or in combination of two or more types thereof.

Examples of the cardo resin include a resin having a cardo structure, that is, a skeleton structure in which two cyclic structures are bonded to a quaternary carbon atom constituting a cyclic structure. A common cardo structure is a fluorene ring bonded to a benzene ring.

Specific examples of the skeleton structure in which two cyclic structures are bonded to a quaternary carbon atom constituting a cyclic structure include a fluorene skeleton, a bisphenol fluorene skeleton, a bisaminophenyl fluorene skeleton, a fluorene skeleton having an epoxy group, and a fluorene skeleton having an acrylic group.

The cardo resin is formed by polymerizing a skeleton having the cardo structure by, for example, a reaction between functional groups bonded to the skeletons. The cardo resin has a structure in which a main chain and a bulky side chain are connected by one element (cardo structure), and has a cyclic structure in a direction substantially perpendicular to the main chain.

Specific examples of the monomer having a cardo structure include publicly known substances such as bisphenols containing a cardo structure such as bis(glycidyloxyphenyl)fluorene type epoxy resin, 9,9-bis(4-hydroxyphenyl)fluorene, and 9,9-bis(4-hydroxy-3-methylphenyl)fluorene, 9,9-bis(cyanoalkyl)fluorenes such as 9,9-bis(cyanomethyl)fluorene, and 9,9-bis(aminoalkyl)fluorenes such as 9,9-bis(3-aminopropyl)fluorene.

The cardo resin is a polymer obtained by polymerizing a monomer having a cardo structure, but may be a copolymer with another copolymerizable monomer.

Examples of the phenol resin include publicly known phenol resins such as a novolac phenol resin and a resol phenol resin, and the phenol resin is obtained by polycondensation of various phenols alone or a mixture of a plurality of phenols thereof with an aldehyde such as formalin.

Examples of the phenols constituting the novolac phenol resin and the resol phenol resin include phenol, p-cresol, m-cresol, o-cresol, 2,3-dimethylphenol, 2,4-dimethylphenol, 2,5-dimethylphenol, 2,6-dimethylphenol, 3,4-dimethylphenol, 3,5-dimethylphenol, 2,3,4-trimethylphenol, 2,3,5-trimethylphenol, 3,4,5-trimethylphenol, 2,4,5-trimethylphenol, methylenebisphenol, methylenebis p-cresol, resorcin, catechol, 2-methylresorcin, 4-methylresorcin, o-chlorophenol, m-chlorophenol, p-chlorophenol, 2,3-dichlorophenol, m-methoxyphenol, p-methoxyphenol, p-butoxyphenol, o-ethylphenol, m-ethylphenol, p-ethylphenol, 2,3-diethylphenol, 2,5-diethylphenol, p-isopropylphenol, α-naphthol, and β-naphthol, and these can be used singly or as a mixture of two or more.

In addition to formalin, examples of aldehydes include paraformaldehyde, acetaldehyde, benzaldehyde, hydroxybenzaldehyde, and chloroacetaldehyde, and these can be used singly or as a mixture of two or more.

Examples of the polysiloxane include publicly known polysiloxanes obtained by hydrolysis and dehydration condensation of one or more types selected from a tetrafunctional organosilane, a trifunctional organosilane, a bifunctional organosilane, and a monofunctional organosilane.

Specific examples of the organosilane include tetrafunctional silanes such as tetramethoxysilane, tetraethoxysilane, tetraacetoxysilane, and tetraphenoxysilane, trifunctional silanes such as methyltrimethoxysilane, methyltriethoxysilane, ethyltrimethoxysilane, ethyltriethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, phenyltrimethoxysilane, phenyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, trimethoxysilane, 3,3,3-trifluoropropyltrimethoxysilane, 3-aminopropyltrimethoxysilane, 3-aminopropyltrimethoxysilane, 3-aminopropyltrimethoxys, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, 3-trimethoxysilylpropylsuccinic acid, 1-naphthyltrimethoxysilane, 1-naphthyltriethoxysilane, 1-naphthyltri-n-propoxysilane, and 2-naphthyltrimethoxysilane, bifunctional silanes such as dimethyldimethoxysilane, dimethyldiethoxysilane, dimethyldiacetoxysilane, din-butyldimethoxysilane, diphenyldimethoxysilane, (3-glycidoxypropyl)methyldimethoxysilane, (3-glycidoxypropyl)methyldiethoxysilane, di(1-naphthyl)dimethoxysilane, and di(1-naphthyl)diethoxysilane; and monofunctional silanes such as trimethylmethoxysilane, tri n-butylethoxysilane, (3-glycidoxypropyl)dimethylmethoxysilane, and (3-glycidoxypropyl)dimethylethoxysilane. Two or more types of these organosilanes may be used. In addition, a silicate compound such as Methyl Silicate 51 manufactured by FUSO CHEMICAL CO., LTD., or M Silicate 51 manufactured by TAMA CHEMICAL CO., LTD., may be copolymerized.

The polysiloxane is synthesized by hydrolysis and partial condensation of monomers such as organosilanes. Herein, the partial condensation does not mean condensation of all Si—OH of the hydrolysate, but means that a part of Si—OH remains in the resulting polysiloxane. General methods can be used for hydrolysis and partial condensation. Examples thereof include a method in which a solvent, water, and a catalyst as necessary are added to the organosilane mixture, and the mixture is heated and stirred at 50 to 150° C. for about 0.5 to 100 hours. During stirring, if necessary, a hydrolysis by-product (alcohols such as methanol) and a condensation by-product (water) may be distilled off by distillation.

The catalyst is not particularly limited, but an acid catalyst and a base catalyst are preferably used. Specific examples of the acid catalyst include hydrochloric acid, nitric acid, sulfuric acid, hydrofluoric acid, phosphoric acid, acetic acid, trifluoroacetic acid, formic acid, a polycarboxylic acid or an anhydride thereof, and an ion exchange resin. Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, alkoxysilane having an amino group, and an ion exchange resin.

The solvent used for producing the component (a) is not particularly limited, and examples thereof can include alkylene glycol monoalkyl ethers such as ethylene glycol monomethyl ether and propylene glycol monomethyl ether, alkyl acetates such as propyl acetate, butyl acetate, and isobutyl acetate, ketones such as methyl isobutyl ketone and methyl propyl ketone, alcohols such as butyl alcohol and isobutyl alcohol, ethyl lactate, butyl lactate, dipropylene glycol dimethyl ether, diethylene glycol dimethyl ether, diethylene glycol ethyl methyl ether, diethylene glycol diethyl ether, 3-methoxybutyl acetate, ethylene glycol monoethyl ether acetate, gamma butyrolactone, N-methyl-2-pyrrolidone, diacetone alcohol, N-cyclohexyl-2-pyrrolidone, N,N-dimethylformamide, N,N-dimethylacetamide, dimethyl sulfoxide, propylene glycol monomethyl ether acetate, N,N-dimethylisobutyramide, 3-methoxy-N,N-dimethylpropionamide, 3-butoxy-N,N-dimethylpropionamide, 1,3-dimethyl-2-imidazolidinone, N,N-dimethylpropyleneurea, delta valerolactone, 2-phenoxyethanol, 2-pyrrolidone, 2-methyl-1,3-propanediol, diethylene glycol butyl ether, triacetin, butyl benzoate, cyclohexylbenzene, bicyclohexyl, o-nitroanisole, diethylene glycol monobutyl ether, triethylene glycol monomethyl ether, N-(2-hydroxyethyl)-2-pyrrolidone, N,N-dimethylpropanamide, N,N-dimethylisobutyramide, N,N,N′,N′-tetramethylurea, and 3-methyl-2-oxazolidinone.

### <Aromatic Hydrocarbon (b) Having at Least One Aromatic C—H Bond and at Least Three Phenolic Hydroxyl Groups in One Aromatic Ring>

The photosensitive resin composition of the present invention further includes an aromatic hydrocarbon (b) (hereinafter, may be referred to as a component (b)) having at least one aromatic C—H bond and at least three phenolic hydroxyl groups in one aromatic ring. The photosensitive resin composition of the present invention contains the component (b) and the thermal cross-linking agent (c) having a partial structure represented by the formula (1) described later, thereby developing color by heating regardless of the atmosphere during curing, and allowing to reduce the transmittance of 300 nm to 500 nm after curing. Although the color development mechanism is not clear, it is considered that the crosslinking reaction proceeds by heating between the aromatic C—H bond in the component (b) and the thermal cross-linking agent (c) having a partial structure represented by the formula (1), and the crosslinked body has a quinone structure, thereby a color former having absorption at 300 nm to 500 nm is generated. The crosslinking reaction does not depend on the heating atmosphere during curing, and thus the transmittance of 300 nm to 500 nm after curing can be reduced without being restricted by the curing conditions. In a state before heating, both the component (b) and the thermal cross-linking agent (c) having a partial structure represented by the formula (1) have no absorption in a wavelength range of 300 nm to 500 nm, and thus before curing, do not shield the exposure wavelength range of 350 nm to 450 nm of a mercury lamp generally used as an exposure light source, and a pattern can be formed with high sensitivity. Further, a film having high visible light shielding property after curing can be obtained by containing the colorant (d) having a maximum absorption wavelength in any of the range of 490 nm or more and less than 800 nm at 300 to 800 nm to be described later, and having 0.1% or more and less than 60% of a ratio of the absorbance Abs₃₆₅ at 365 nm to the absorbance Absₘₐₓ at the maximum absorption wavelength.

Examples of the aromatic hydrocarbon structure of the component (b) include known monocyclic and condensed polycyclic structures. In addition, the aromatic hydrocarbon has at least one aromatic C—H bond and at least three phenolic hydroxyl groups in one aromatic ring. The aromatic hydrocarbon having at least one aromatic C—H bond in one aromatic ring represents the presence of one or more unsubstituted aromatic C—H bonds in the aromatic ring. In the present invention, the state having at least one aromatic C—H bond and at least three phenolic hydroxyl groups in one aromatic ring represents a state having at least one aromatic C—H bond and at least three phenolic hydroxyl groups in a single aromatic ring, and for example, a compound having three aromatic rings having at least one aromatic C—H bond and one phenolic hydroxyl group is not included in the aspect of the present invention. Specific examples of the component (b) include, but are not limited to, the structures shown below.

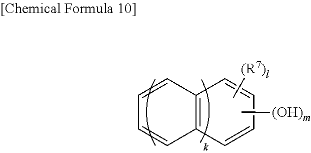

R⁷ independently represents a monovalent organic group having 1 to 20 carbon atoms, k represents an integer of 0 to 2, 1 represents an integer of 0 to 6, and m represents an integer of 3 to 9. Herein, {(2k+6)−(1+m)}≥1.

The component (b) has at least one aromatic C—H bond in one aromatic ring, thereby allowing to form a crosslinked body made of the thermal cross-linking agent (c) having a partial structure represented by the formula (1) described later, and allowing to reduce the transmittance of 300 nm to 500 nm after curing. The number of aromatic C—H bonds in one aromatic ring in the component (b) is one or more, preferably two or more, and more preferably three or more. It is preferable that the number of aromatic C—H bonds in one aromatic ring is larger because the number of crosslinking points with the thermal cross-linking agent (c) having a partial structure represented by the formula (1) increases, thereby allowing to reduce the transmittance at 300 nm to 500 nm after curing.

Examples of the aromatic hydrocarbon having at least one aromatic C—H bond and three phenolic hydroxyl groups in one aromatic ring include phloroglucinol, pyrogallol, 1,2.4-trihydroxybenzene, 2,4,5-trihydroxybenzaldehyde, 2,3,4-trihydroxybenzaldehyde, 3,4,5-trihydroxybenzaldehyde, gallacetophenone, 2,3,4-trihydroxybenzoic acid, gallic acid, methyl gallate, ethyl gallate, propyl gallate, octyl gallate, 2,3,4-trihydroxybenzophenone, 2,3,4,4′-tetrahydroxybenzophenone, and 4,4′-isopropylidenedipyrogallol. Examples of the aromatic hydrocarbon having at least one aromatic C—H bond and four or more phenolic hydroxyl groups in one aromatic ring include 1,2,3,4-tetrahydroxybenzene, 1,2,3,5-tetrahydroxybenzene, 1,2,4,5-tetrahydroxybenzene, and leucoquinizarin.

From the viewpoint of further lowering the transmittance of 300 nm to 500 nm after curing, as the component (b), with respect to any of the phenolic hydroxyl groups in the component (b), at least one substitution position of other phenolic hydroxyl groups is an ortho position or a para position, and more preferably a para position. With respect to any of the phenolic hydroxyl groups, at least one substitution position of other phenolic hydroxyl groups is an ortho position or a para position, thereby allowing to reduce the transmittance at 300 nm to 500 nm after curing. This is presumed to be because the crosslinked body after curing of the component (b) and the thermal cross-linking agent (c) having a partial structure represented by the formula (1) has an orthoquinone or paraquinone structure, thereby further increasing the color developability.

Examples of the compound (b1) in which, with respect to any of the phenolic hydroxyl groups, at least one substitution position of other phenolic hydroxyl groups is an ortho position among the components (b) include pyrogallol, 1,2.4-trihydroxybenzene, 2,4,5-trihydroxybenzaldehyde, 2,3,4-trihydroxybenzaldehyde, 3,4,5-trihydroxybenzaldehyde, gallacetophenone, 2,3,4-trihydroxybenzoic acid, gallic acid, methyl gallate, ethyl gallate, propyl gallate, octyl gallate, 2,3,4-trihydroxybenzophenone, 2,3,4,4′-tetrahydroxybenzophenone, 4,4′-isopropylidenedipyrogallol, 1,2,3,4-tetrahydroxybenzene, 1,2,3,5-tetrahydroxybenzene, and 1,2,4,5-tetrahydroxybenzene. Examples of the compound (b2) in which at least one substitution position of the other phenolic hydroxyl groups with respect to any of the phenolic hydroxyl groups is the para position among the components (b) include 1,2.4-trihydroxybenzene, 2,4,5-trihydroxybenzaldehyde, 1,2,3,4-tetrahydroxybenzene, 1,2,3,5-tetrahydroxybenzene, 1,2,4,5-tetrahydroxybenzene, and leucoquinizarin.

The upper limit of the molecular weight of the component (b) is not particularly limited, but is preferably 1000 or less, more preferably 800 or less, still more preferably 600 or less. The lower limit of the molecular weight of the component (b) is 126 or more.

In the present invention, the content of the component (b) is preferably 1 part by mass or more, more preferably 5 parts by mass or more, still more preferably 10 parts by mass or more with respect to 100 parts by mass of the component (a). Setting the content of the component (b) to 1 part by mass or more with respect to 100 parts by mass of the component (a) can reduce the transmittance of 300 nm to 500 nm after curing in combination with the thermal cross-linking agent (c) having a partial structure represented by the formula (1) described later. In addition, the content of the component (b) is preferably 50 parts by mass or less, more preferably 40 parts by mass or less, still more preferably 30 parts by mass or less, particularly preferably 20 parts by mass or less with respect to 100 parts by mass of the component (a). Setting the content of the component (b) to 50 parts by mass or less with respect to 100 parts by mass of the component (a) can maintain the chemical resistance of the cured article.

### <Thermal Cross-Linking Agent (c) Having Partial Structure Represented by Formula (1)>

The photosensitive resin composition of the present invention further contains a thermal cross-linking agent (c) (hereinafter, may be referred to as a component (c)) having a partial structure represented by the formula (1).

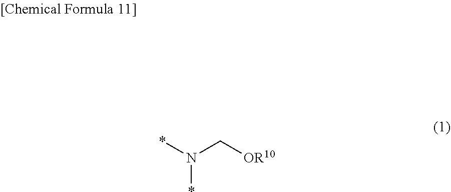

R¹⁰ represents a hydrogen atom or an alkyl group. * each represents a bond, but a carbonyl group is not adjacent to a nitrogen atom.

The photosensitive resin composition of the present invention contains the component (c) and the component (b), thereby developing color by heating regardless of the atmosphere during curing, and allowing to reduce the transmittance of 300 nm to 500 nm after curing. The component (c) has a partial structure represented by the formula (1), that is, a methylol group or an alkoxymethyl group directly substituted with a nitrogen atom, thereby allowing to form a crosslinked body with the component (b). The component (c) preferably has two or more, more preferably three or more, still more preferably four or more, and most preferably six or more of partial structures represented by the formula (1) in the molecule. A larger number of partial structures represented by the formula (1) is preferable because the more crosslinking points with the component (b) can further reduce the transmittance at 300 nm to 500 nm after curing. In the partial structure represented by the formula (1), when two methylol groups or alkoxymethyl groups are bonded from the same nitrogen atom, two partial structures represented by the formula (1) are regarded as being present in the molecule. The upper limit of the partial structure represented by the formula (1) contained in the molecule of the component (c) is not particularly limited, but is, for example, 20 or less. R¹⁰ represents a hydrogen atom or an alkyl group, and R¹⁰ is preferably an alkyl group having 1 to 10 carbon atoms from the viewpoint of enhancing the storage stability of the photosensitive resin composition. Examples of the alkyl group include a methyl group, an ethyl group, a propyl group, and a butyl group.

In the partial structure represented by the formula (1), a carbonyl group is not adjacent to a nitrogen atom. The methylol group or the alkoxymethyl group in the formula (1) is directly bonded to a nitrogen atom that is not adjacent to the carbonyl group, thereby enhancing the reactivity of the methylol group or the alkoxymethyl group, and the formation of a crosslinked body with the component (b) is promoted, thereby allowing to reduce the transmittance at 300 nm to 500 nm after curing.

In the partial structure represented by the formula (1), the substituent adjacent to the nitrogen atom is not particularly limited as long as it is other than a carbonyl group, and a hydrogen atom, a methylol group, an alkoxymethyl group, an alkyl group which may have a substituent, an alkenyl group which may have a substituent, an alkenyl ether group which may have a substituent, an aryl group which may have a substituent, a heteroaryl group which may have a substituent, or the like can be adjacent. From the viewpoint of enhancing the reactivity of the methylol group or the alkoxymethyl group, as the substituent adjacent to the nitrogen atom in the formula (1), at least one aryl group which may have a substituent or a heteroaryl group which may have a substituent is preferably adjacent, and examples thereof include compounds having the structures shown below, but are not limited thereto.

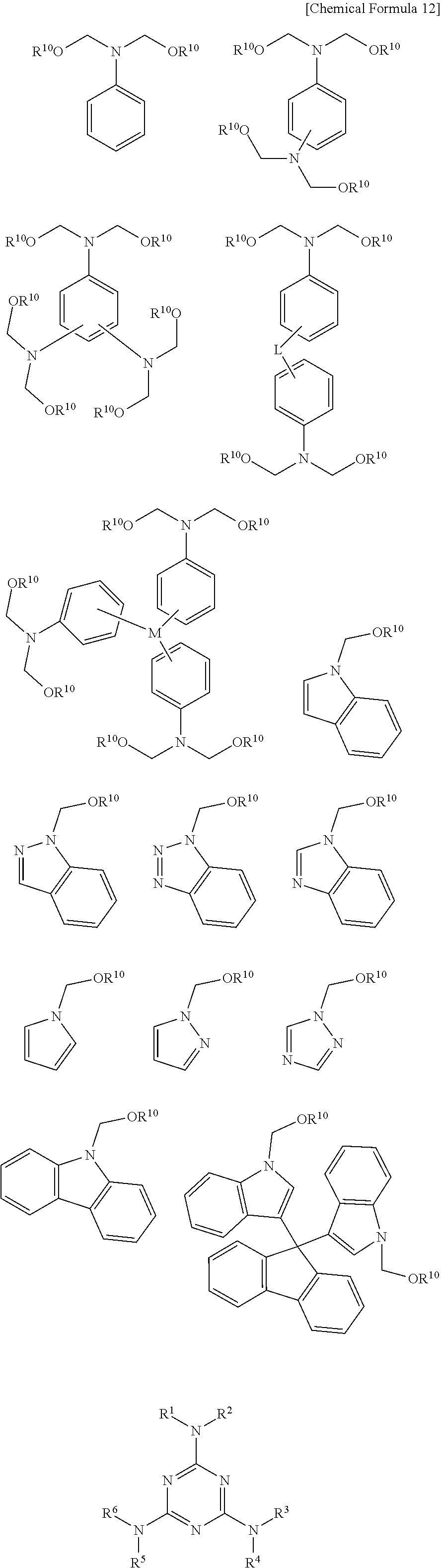

R¹⁰ each independently represents a hydrogen atom or an alkyl group. L represents a single bond, an oxygen atom, C(CF₃)₂, C(CH₃)₂, SO₂, or CO. M represents a nitrogen atom, CH, or CCH₃. R¹ to R⁶ each independently represent a hydrogen atom, an alkyl group having 1 to 10 carbon atoms, an alkenyl group having 2 to 10 carbon atoms, an alkenyl ether group having 2 to 10 carbon atoms, a methylol group, or an alkoxymethyl group. At least one of R¹ to R⁶ is a methylol group or an alkoxymethyl group.

From the viewpoint of further lowering the transmittance of 300 nm to 500 nm after curing, the component (c) of the present invention preferably contains a triazine ring-containing compound (c1) represented by the formula (2) (hereinafter, may be referred to as a component (c1)). That is, the photosensitive resin composition of the present invention is preferably a photosensitive resin composition containing an alkali-soluble resin (a), an aromatic hydrocarbon (b) having at least one aromatic C—H bond and at least three phenolic hydroxyl groups in one aromatic ring, a triazine ring-containing compound represented by the formula (2), and a photosensitive compound (e).

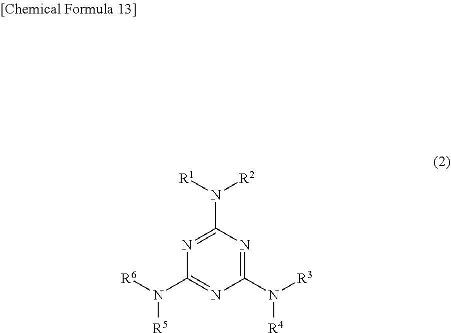

In the formula (2), R¹ to R⁶ each independently represent a hydrogen atom, an alkyl group having 1 to 10 carbon atoms, an alkenyl group having 2 to 10 carbon atoms, an alkenyl ether group having 2 to 10 carbon atoms, a methylol group, or an alkoxymethyl group. At least one of R¹ to R⁶ is a methylol group or an alkoxymethyl group.

In order to form a crosslinked body of the component (c1) and the component (b), at least one of R¹ to R⁶ has a methylol group or an alkoxymethyl group, and the number of the methylol group or the alkoxymethyl group is preferably two or more, more preferably three or more, still more preferably four or more, and most preferably all six are a methylol group or an alkoxymethyl group. A larger number of methylol groups or alkoxymethyl groups is preferable because the number of crosslinking points with the component (b) increases, thereby allowing to further reduce the transmittance at 300 nm to 500 nm after curing.

Examples of the alkoxymethyl group include a methoxymethyl group, an ethoxymethyl group, a propoxymethyl group, and a butoxymethyl group.

As the component (c), in addition to a commercially available product, a component synthesized by a known method can be used. As a known method, for example, a compound in which a methylol group is substituted on a nitrogen atom can be obtained by reacting a primary amino group or a secondary amino group-containing compound with formaldehyde under basic conditions. Further, reacting with an alcohol under acidic conditions can provide a compound in which an alkoxymethyl group is substituted on a nitrogen atom.

The upper limit of the molecular weight of the component (c) is not particularly limited, but is preferably 1000 or less, more preferably 800 or less, still more preferably 600 or less. The lower limit of the molecular weight of the component (c) is 47 or more.

In the present invention, the content of the component (c) is preferably 1 part by mass or more, more preferably 5 parts by mass or more, still more preferably 10 parts by mass or more, with respect to 100 parts by mass of the alkali-soluble resin (a). Setting the content of the component (c) to 1 part by mass or more can reduce the transmittance of 300 nm to 500 nm after curing in combination with the component (b). In addition, the content of the component (c) is preferably 100 parts by mass or less, more preferably 80 parts by mass or less, still more preferably 50 parts by mass or less, particularly preferably 30 parts by mass or less with respect to 100 parts by mass of the component (a). Setting the content of the component (c) to 100 parts by mass or less can improve the sensitivity of the photosensitive resin composition.

<Photosensitive Compound (e)>

The photosensitive resin composition of the present invention further contains a photosensitive compound (e) (hereinafter, may be referred to as a component (e)).

The content of the component (e) is preferably 0.1 parts by mass or more, more preferably 1 part by mass or more, still more preferably 10 parts by mass or more with respect to 100 parts by mass of the component (a) from the viewpoint of increasing the sensitivity. On the other hand, from the viewpoint of long-term reliability when the cured article of the present invention is used as a planarization layer and/or an insulating layer of an organic EL display device, the content of the component (e) is preferably 100 parts by mass or less with respect to 100 parts by mass of the component (a). As the component (e), a photo acid generator (e1), a photo initiator (e2), and the like can be contained. The photo acid generator (e1) is a compound that generates an acid when irradiated with light, and the photo initiator (e2) is a compound that generates a radical by bond cleavage and/or reaction when exposed.

By the fact that the photo acid generator (e1) is included, a positive relief pattern can be obtained in which the part irradiated with light is dissolved because an acid is generated in the part irradiated with light to increase the solubility of the part in an alkali aqueous solution. Furthermore, by the fact that the photo acid generator (e1) and an epoxy compound or a thermal cross-linking agent described below are contained, a negative relief pattern can be obtained in which the part irradiated with light is insolubilized because the acid generated in the part irradiated with light promotes the crosslinking reaction of the epoxy compound or the thermal cross-linking agent. By the fact that the photo initiator (e2) and a radically polymerizable compound described below are contained, a negative relief pattern can be obtained in which the part irradiated with light is insolubilized because radical polymerization proceeds in the part irradiated with light. From the viewpoint that a fine pattern can be formed when the cured article of the present invention is used as a planarization layer and/or an insulating layer in an organic EL display device, it is preferable to contain the photo acid generator (e1) capable of obtaining a positive relief pattern as the compound (e).

As the photo acid generator (e1), for example, a quinone diazide compound can be contained. The photosensitive resin composition of the present invention preferably contains two or more photo acid generators (e1), and when the photosensitive resin composition contains two or more photo acid generators, a photosensitive resin composition having further high sensitivity can be obtained.

Examples of the quinone diazide compound can include compounds in which a sulfonic acid of quinonediazide is bonded to a polyhydroxy compound to form an ester, compounds in which a sulfonic acid of quinonediazide is sulfonamide-bonded to a polyamino compound, and compounds in which a sulfonic acid of quinonediazide is ester-bonded and/or sulfonamide-bonded to a polyhydroxypolyamino compound.

As the quinone diazide structure, either a 5-naphthoquinone diazide sulfonyl group or a 4-naphthoquinone diazide sulfonyl group is preferably used. A naphthoquinone diazide sulfonyl ester compound having a 4-naphthoquinone diazide sulfonyl group and a 5-naphthoquinone diazide sulfonyl group in one molecule may be included, or a 4-naphthoquinone diazide sulfonyl ester compound and a 5-naphthoquinone diazide sulfonyl ester compound may be included. The 4-naphthoquinone diazide sulfonyl ester compound has absorption in the i-line region of a mercury lamp, and is suitable for i-line exposure. The 5-naphthoquinone diazide sulfonyl ester compound has an absorption in a region extending to the g-line region of a mercury lamp, and is suitable for g-line exposure.

It is preferable to select a 4-naphthoquinone diazide sulfonyl ester compound or a 5-naphthoquinone diazide sulfonyl ester compound according to the wavelength of light for exposure, but a 4-naphthoquinone diazide sulfonyl ester compound is preferably included from the viewpoint of enhancing the sensitivity.

The quinone diazide compound can be synthesized by an arbitrary esterification reaction from a compound having a phenolic hydroxyl group and a quinone diazide sulfonic acid compound. Use of these quinone diazide compounds leads to further improvement in the resolution, the sensitivity, and the residual film rate.

The content of the photo acid generator (e1) is preferably 0.1 parts by mass or more, more preferably 10 parts by mass or more, still more preferably 25 parts by mass or more with respect to 100 parts by mass of the component (a) from the viewpoint of increasing the sensitivity. On the other hand, from the viewpoint of long-term reliability when the cured article of the present invention is used as a planarization layer and/or an insulating layer of an organic EL display device, the content of the photo acid generator (e1) is preferably 100 parts by mass or less with respect to 100 parts by mass of the component (a).

Examples of the photo initiator (e2) can include benzyl ketal-based photo initiators, α-hydroxyketone-based photo initiators, α-aminoketone-based photo initiators, acylphosphine oxide-based photo initiators, oxime ester-based photo initiators, acridine-based photo initiators, titanocene-based photo initiators, benzophenone-based photo initiators, acetophenone-based photo initiators, aromatic ketoester-based photo initiators, and benzoic acid ester-based photo initiators. The photosensitive resin composition of the present invention may contain two or more of the photo initiators (e2). From the viewpoint of further improving the sensitivity, the photo initiator (e2) still more preferably includes an α-aminoketone-based photo initiator, an acylphosphine oxide-based photo initiator, or an oxime ester-based photo initiator.

Examples of the α-aminoketone-based photo initiator can include 2-methyl-1-[4-(methylthio)phenyl]-2-morpholinopropane-1-one, 2-benzyl-2-dimethylamino-1-(4-morpholinophenyl)-butan-1-one, 2-dimethylamino-2-(4-methylbenzyl)-1-(4-morpholinophenyl)-butan-1-one, and 3,6-bis(2-methyl-2-morpholinopropionyl)-9-octyl-9H-carbazole.

Examples of the acylphosphine oxide-based photo initiator can include 2,4,6-trimethylbenzoyl-diphenylphosphine oxide, bis(2,4,6-trimethylbenzoyl)-phenylphosphine oxide, and bis(2,6-dimethoxybenzoyl)-(2,4,4-trimethylpentyl)phosphine oxide.

Examples of the oxime ester-based photo initiator can include 1-phenylpropane-1,2-dione-2-(0-ethoxycarbonyl)oxime, 1-phenylbutane-1,2-dione-2-(0-methoxycarbonyl)oxime, 1,3-diphenylpropane-1,2,3-trione-2-(0-ethoxycarbonyl)oxime, 1-[4-(phenylthio)phenyl]octane-1,2-dione-2-(0-benzoyl)oxime, 1-[4-[4-(carboxyphenyl)thio]phenyl]propane-1,2-dione-2-(0-acetyl)oxime, 1-[9-ethyl-6-(2-methylbenzoyl)-9H-carbazole-3-yl]ethanone-1-(O-acetyl)oxime, 1-[9-ethyl-6-[2-methyl-4-[1-(2,2-dimethyl-1,3-dioxolan-4-yl)methyloxy]benzoyl]-9H-carbazol-3-yl]ethanone-1-(O-acetyl)oxime, and 1-(9-ethyl-6-nitro-9H-carbazole-3-yl)-1-[2-methyl-4-(1-methoxypropane-2-yloxy)phenyl]methanone-1-(0-acetyl)oxime.

The content of the photo initiator (e2) is preferably 0.1 parts by mass or more, more preferably 1 part by mass or more, and still more preferably 10 parts by mass or more, with respect to a total of 100 parts by mass of the component (a) and the radically polymerizable compound described later, from the viewpoint of increasing the sensitivity. On the other hand, from the viewpoint of further improving the resolution and reducing the taper angle, the content of the photo initiator (e2) is preferably 50 parts by mass or less with respect to 100 parts by mass of the total of the component (a) and the radically polymerizable compound described later.

<Colorant (d) Having a Maximum Absorption Wavelength in any of a Range of 490 nm or More and Less than 800 nm at 300 to 800 nm, and Having 0.1% or More and Less than 60% of a Ratio of Absorbance Abs₃₆₅ at 365 nm to Absorbance Absₘₐₓ at the Maximum Absorption Wavelength in any of the Range of 490 nm or More and Less than 800 nm at 300 to 800 nm>

The photosensitive resin composition of the present invention preferably contains a colorant (d) (hereinafter, may be referred to as a component (d)) having a maximum absorption wavelength in any of a range of 490 nm or more and less than 800 nm at 300 to 800 nm, and having 0.1% or more and less than 60% of a ratio of absorbance Abs₃₆₅ at 365 nm to absorbance Absₘₐₓ at the maximum absorption wavelength in any of the range of 490 nm or more and less than 800 nm at 300 to 800 nm. The photosensitive resin composition of the present invention contains the component (b), the component (c), and the component (d), thereby allowing to provide a film having a high visible light shielding properties after curing.

At 300 to 800 nm means that the maximum absorption wavelength is measured in the region of 300 to 800 nm.

The component (d) has a maximum absorption wavelength in any of a range of 490 nm or more and less than 800 nm at 300 to 800 nm. Containing the component (b) and the component (c) can reduce the transmittance of 300 nm to 500 nm after curing, and thus combining the component (d) can shield the entire visible light after curing.

The component (d) has 0.1% or more and less than 60% a ratio of absorbance Abs₃₆₅ at 365 nm to absorbance Absₘₐₓ of the maximum absorption wavelength at any of the ranges of 490 nm or more and less than 800 nm at 300 to 800 nm (hereinafter, ratio of absorbance Abs₃₆₅ to absorbance Absₘₐₓ). The ratio of the absorbance Abs₃₆₅ to the absorbance Absₘₐₓ represents a ratio (%) obtained by dividing the absorbance Abs₃₆₅ by the absorbance Absₘₐₓ and then multiplying the obtained value by 100. The ratio of the absorbance Abs₃₆₅ to the absorbance Absₘₐₓ is 0.1% or more and less than 60%, thereby a pattern can be formed with high sensitivity. From the viewpoint of high sensitivity, the ratio of the absorbance Abs₃₆₅ to the absorbance Absₘₐₓ is less than 60%, preferably less than 40%, more preferably less than 20%, still more preferably less than 15%, and most preferably less than 10%. The lower limit of the ratio of the absorbance Abs₃₆₅ to the absorbance Absₘₐₓ is 0.1% or more. When two or more components (d) are used in combination, it is preferable that one or more components (d) are included in this range, and it is more preferable that all components (d) are included in this range.

As the component (d), it is preferable to contain the dye (d1) and/or the pigment (d2). The component (d) preferably contains at least one dye (d1) or pigment (d2), for example, or contains two or more dyes (d1) or pigments (d2), or contains one or more dyes (d1) and one or more pigments (d2).

From the viewpoint of solvent solubility, the component (d) preferably contains a dye (d1). Further, from the viewpoint of increasing the sensitivity and reducing residues, the dye (d1) is preferably an ionic dye forming an ion pair of organic ions. On the other hand, it is preferable to contain the pigment (d2) from the viewpoint of being able to suppress the discoloration of the colorant in the heat treatment step of the photosensitive resin composition described later.

In addition, from the viewpoint of increasing the sensitivity and reducing the residue, the component (d) preferably has a sulfonic acid group and/or a sulfonate group.

The component (d) preferably contains a colorant (d-1) (hereinafter, may be referred to as a component (d-1)) having a maximum absorption wavelength in a range of 490 nm or more and less than 580 nm at 300 to 800 nm and/or a colorant (d-2) (hereinafter, may be referred to as a component (d-2)) having a maximum absorption wavelength in a range of 580 nm or more and less than 800 nm at 300 to 800 nm. Specifically, the component (d-1) preferably contains a dye (d1-1) having a maximum absorption wavelength in a range of 490 nm or more and less than 580 nm at 300 to 800 nm and/or a pigment (d2-1) having a maximum absorption wavelength in a range of 490 nm or more and less than 580 nm at 300 to 800 nm. Specifically, the component (d-2) preferably contains a dye (d1-2) having a maximum absorption wavelength in a range of 580 nm or more and less than 800 nm at 300 to 800 nm and/or a pigment (d2-2) having a maximum absorption wavelength in a range of 580 nm or more and less than 800 nm at 300 to 800 nm.

The component (d) preferably contains a dye (d1-1) having a maximum absorption wavelength in any of a range of 490 nm or more and less than 580 nm at 300 to 800 nm and/or a dye (d1-2) having a maximum absorption wavelength in any of a range of 580 nm or more and less than 800 nm at 300 to 800 nm.

Hereinafter, the component may be simply referred to as a component (d1-1), a component (d2-1), a component (d1-2), and a component (d2-2), respectively.

In the present invention, the dye (d1) preferably contains a dye soluble in a solvent that dissolves the component (a) and compatible with a resin, and a dye having high heat resistance and light resistance, from the viewpoint of storage stability and discoloration upon curing or irradiation with light. The component (d1-1) has a maximum absorption wavelength in a range of 490 nm or more and less than 580 nm at 300 to 800 nm, and thus examples thereof include a red dye or a purple dye. The component (d1-2) has a maximum absorption wavelength in a range of 580 nm or more and 800 nm or less at 300 to 800 nm, and examples thereof include a blue dye and a green dye. When the photosensitive resin composition of the present invention contains the component (d1-1) and the component (d1-2), from the viewpoint of enhancing the heat resistance and maintaining the visible light shielding property after curing, either the component (d1-1) or the component (d1-2) preferably has a xanthene structure, and both the component (d1-1) and the component (d1-2) more preferably have a xanthene structure.

Examples of the skeleton structure of the dye (d1) include anthraquinone-based, azo-based, phthalocyanine-based, methine-based, oxazine-based, quinoline-based, triarylmethane-based, and xanthene-based structures, but are not limited thereto. Among the skeleton structures, anthraquinone-based, azo-based, methine-based, triarylmethane-based, and xanthene-based structures are preferable from the viewpoint of solubility in a solvent and heat resistance. In addition, from the viewpoint of improving the heat resistance, a xanthene-based structure is more preferable. These dyes may be used singly or as a metal-containing complex salt system. Specifically, examples of available dyes include, but are not limited to, Sumilan Dyes and Lanyl Dyes (produced by Sumitomo Chemical Industry Co., Ltd.); Orasol Dyes, Oracet Dyes, Filamid Dyes, and Irgasperse Dyes (produced by Ciba Specialty Chemicals Co., Ltd.); Zapon Dyes, Neozapon Dyes, Neptune Dyes, and Acidol Dyes (produced by BASF); Kayaset Dyes and Kayakalan Dyes (produced by Nippon Kayaku Co., Ltd.); Valifast Colors Dyes (produced by Orient Chemical Co., Ltd.); Savinyl Dyes, Sandoplast Dyes, Polysynthren Dyes, and Lanasyn Dyes (Produced by Clariant Japan Co., Ltd.); Aizen Spilon Dyes (produced by Hodogaya Chemical Co., Ltd.); functional dyes (produced by Yamada Chemical Co., Ltd.); and Plast Color Dyes and Oil Color Dyes (produced by Arimoto Chemical Co., Ltd.). These dyes are used singly or in combination.

In the present invention, the dye (d1) preferably contains an ionic dye (d1a) (hereinafter, may be referred to as a component (d1a)) forming an ion pair of an organic anion moiety and an organic cation moiety. The component (d1a) refers to a salt forming compound including an organic anion moiety and an organic cation moiety of a non-dye, a salt forming compound including an organic cation moiety of a basic dye and an organic anion moiety of a non-dye, or a salt forming compound including an organic anion moiety of an acidic dye and an organic cation moiety of a basic dye. From the viewpoint of improving the sensitivity by increasing the ratio of the coloring component per molecule and decreasing the amount of the ionic dye added, the ionic dye of the present invention preferably contains a salt forming compound including an organic anion moiety of an acidic dye and an organic cation moiety of a basic dye. That is, it is preferable that the component (d) contains an ionic dye forming an ion pair of an organic anion moiety and an organic cation moiety, and the organic anion moiety and the organic cation moiety is made of an organic anion moiety of an acidic dye and an organic cation moiety of a basic dye, respectively.

The salt forming compound including an organic anion moiety of an acidic dye and an organic cation moiety of a non-dye can be produced by using the acidic dye as a raw material and exchanging the counter cation with the organic cation of the non-dye by a known method. The salt forming compound including an organic cation moiety of a basic dye and an organic anion moiety of a non-dye can be produced by using the basic dye as a raw material and exchanging the counter anion with the organic anion of the non-dye by a known method. The salt forming compound including an organic anion moiety of an acidic dye and an organic cation moiety of a basic dye can be produced by using the acidic dye and the basic dye as raw materials and exchanging the counter ions of the acidic dye and the basic dye by a known method.

The acidic dye as a raw material of the component (d1a) is an anionic water-soluble dye which is a compound having an acidic substituent such as a sulfo group or a carboxy group in the molecule of the dye or a salt thereof. The acidic dye includes those having an acidic substituent such as a sulfo group or a carboxy group and classified as a direct dye.

Examples of the acidic dye include azo-based acidic dyes such as C.I. Acid Yellow 1, 17, 18, 23, 25, 36, 38, 42, 44, 54, 59, 72, 78, and 151; C.I. Acid Orange 7, 10, 12, 19, 20, 22, 28, 30, 52, 56, 74, and 127; C.I. Acid Red 1, 3, 4, 6, 8, 11, 12, 14, 18, 26, 27, 33, 37, 53, 57, 88, 106, 108, 111, 114, 131, 137, 138, 151, 154, 158, 159, 173, 184, 186, 215, 257, 266, 296, and 337; C.I. Acid Brown 2, 4, 13, and 248; C.I. Acid Violet 11, 56, and 58; and C.I. Acid Blue 92, 102, 113, and 117; quinoline-based acidic dyes such as C.I. Acid Yellow 2, 3, and 5; xanthene-based acidic dyes such as C.I. Acid Red 50, 51, 52, 87, 91, 92, 93, 94, and 289; anthraquinone-based acidic dyes such as C.I. Acid Red 82 and 92; C.I. Acid Violet 41, 42, and 43; C.I. Acid Blue 14, 23, 25, 27, 40, 45, 78, 80, 127:1, 129, 145, 167, and 230; and C.I. Acid Green 25 and 27; triarylmethane-based acidic dyes such as C.I. Acid Violet 49; C.I. Acid Blue 7, 9, 22, 83, and 90; C.I. Acid Green 9 and 50; and C.I. Food Green 3; phthalocyanine-based acidic dyes such as C.I. Acid Blue 249; and indigoid-based acidic dyes such as C.I. Acid Blue 74. Among them, the acid dye preferably includes xanthene-based acidic dyes from the viewpoint of high heat resistance. The xanthene-based acidic dyes more preferably include a rhodamine-based acidic dyes such as C.I. Acid Red 50, 52, and 289.

Examples of the organic cation moiety of the non-dye as a raw material of the component (d1a) include ammonium ions [N(R)₄]⁺, phosphonium ions [P(R)₄]⁺, iminium ions [(R)₂—N═C(R)₂]⁺, arsonium ions [As(R)₄]⁺, stibonium ions [Sb(R)₄]⁺, oxonium ions [O(R)₃]⁺, sulfonium ions [S(R)₃]⁺, selenonium ions [Se(R)]+, stannonium ions [Sn(R)₃]⁺, iodonium ions [I(R)₂]⁺, and diazonium ions [R—N⁺≡N]. From the viewpoint of insulation properties when the cured article formed of the photosensitive resin composition of the present invention is applied, ammonium ions [N(R)₄]⁺, phosphonium ions [P(R)₄]⁺, and iminium ions [(R)₂—N═C(R)₂]⁺ are preferable. R in the ionic formula is each independently a hydrocarbon group having 1 to 20 carbon atoms which may have a substituent and may have a heteroatom in the carbon chain. From the viewpoint of improving the sensitivity by increasing the ratio of the coloring component per molecule and decreasing the content of the ionic dye in the photosensitive resin composition, the molecular weight of the organic cation moiety of the non-dye is preferably 1000 or less, more preferably 700 or less, still more preferably 400 or less. The lower limit of the molecular weight of the organic cation moiety of the non-dye is not particularly limited, and is preferably 1 or more and still more preferably 100 or more.

The basic dye as a raw material of the component (d1a) is a compound having a basic group, such as such as an amino group or an imino group, in the molecule or a salt thereof, and is a dye that becomes a cation in an aqueous solution.

Examples of the basic dye include azo-based basic dyes such as C.I. Basic Red 17, 22, 23, 25, 29, 30, 38, 39, 46, 46:1, and 82; C.I. Basic Orange 2, 24, and 25; C.I. Basic Violet 18; C.I. Basic Yellow 15, 24, 25, 32, 36, 41, 73, and 80; C.I. Basic Brown 1; and C.I. Basic Blue 41, 54, 64, 66, 67, and 129; xanthene-based basic dyes such as C.I. Basic Red 1 and 2; and C.I. Basic Violet 10 and 11; methine-based basic dyes such as C.I. Basic Yellow 11, 13, 21, 23, and 28; C.I. Basic Orange 21; C.I. Basic Red 13 and 14; and C.I. Basic Violet 16 and 39; anthraquinone-based basic dyes such as C.I. Basic Blue 22, 35, 45, and 47; triarylmethane-based basic dyes such as C.I. Basic Violet 1, 2, 3, 4, 13, 14, and 23; C.I. Basic Blue 1, 5, 7, 8, 11, 15, 18, 21, 24, and 26; and C.I. Basic Green 1 and 4, and xanthene-based basic dyes having the structures presented below.

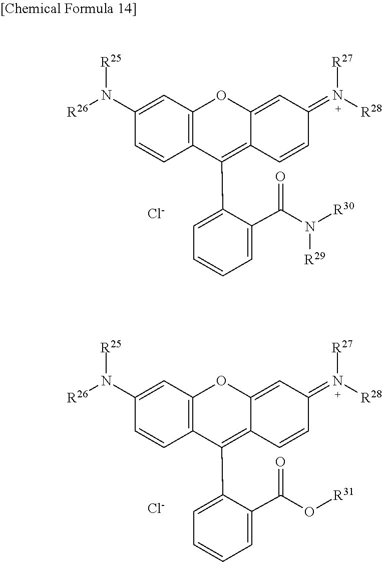

R²⁵ to R³¹ each independently represent a hydrogen atom, an alkyl group having 1 to 10 carbon atoms, or an aryl group having 6 to 10 carbon atoms which may have a substituent.

Among them, the basic dye preferably includes xanthene-based basic dyes and triarylmethane-based basic dyes from the viewpoint of increasing the blackness of the cured article, and preferably includes xanthene-based acidic dyes from the viewpoint of high heat resistance.

Examples of the organic anion moiety of the non-dye as a raw material of the component (d1a) include, in addition to aliphatic or aromatic sulfonate ions and aliphatic or aromatic carboxylate ions, sulfonimide anions [(RSO₂)₂N]⁻ and borate anions (BR₄)⁻. The organic anion moiety of the non-dye is preferably an aliphatic or aromatic sulfonate ion or an aliphatic or aromatic carboxylate ion from the viewpoint of suppressing deterioration of an electrode or a light-emitting layer of an organic EL display device when a cured article formed of the photosensitive resin composition of the present invention is applied. Further, from the viewpoint of increasing the sensitivity and reducing residues, the organic anion moiety of the non-dye is preferably an aliphatic or aromatic sulfonate ion. In the ionic formula of the organic anion moiety of the non-dye, R each independently represents a hydrocarbon group having 1 to 20 carbon atoms which may have a substituent or a heteroatom in the carbon chain. From the viewpoint of improving the sensitivity by increasing the ratio of the coloring component per molecule and decreasing the content of the ionic dye in the photosensitive resin composition, the molecular weight of the organic anion moiety of the non-dye is preferably 1000 or less, more preferably 700 or less, still more preferably 400 or less. The lower limit of the molecular weight of the anion site of the non-dye is not particularly limited, and is preferably 1 or more and still more preferably 100 or more.

From the viewpoint of high heat resistance, the organic anion moiety and/or the organic cation moiety of the component (d1a) preferably has a xanthene skeleton. Examples of the organic anion having a xanthene skeleton include the xanthene-based acidic dyes described above, and examples of the organic cation having a xanthene skeleton include the xanthene-based basic dyes described above.

The component (d1a) preferably has an acidic group from the viewpoint of enhancing alkali solubility during development and improving the sensitivity. As the acidic group, the component (d1a) can have, for example, a carboxy group, a phenolic hydroxyl group, a sulfonic acid group, a sulfonate group, or the like, and a sulfonic acid group or a sulfonate group is particularly preferable.

A salt forming compound obtained by ion exchange of the acidic dye or the basic dye can be produced by a known method. For example, when an aqueous solution of an acidic dye and an aqueous solution of a basic dye are prepared and both are slowly mixed under stirring, a salt forming compound including an organic anion moiety of the acidic dye and an organic cation moiety of the basic dye is produced as a precipitate. The salt forming compound can be obtained by collecting the precipitate by filtration. The obtained salt forming compound is preferably dried at about 60 to 70° C.

The photosensitive resin composition of the present invention may contain two or more types of the components (d1a), but when the photosensitive resin composition of the present invention contains n types of the components (d1a), the organic ions contained in the photosensitive resin composition are preferably of (n+1) types. n represents an integer of 2 to 10. As used herein, the organic ion contained in the photosensitive resin composition refers not only to the organic ion constituting the ionic dye but also to all the organic ions contained in the photosensitive resin composition. For example, when the photosensitive resin composition contains n types of the components (d1a) in which organic anion moieties are different from each other and organic cation moieties are different from each other, organic ions contained in the photosensitive resin composition are (n×2) types. In this case, the presence of a plurality of organic anions and organic cations in the photosensitive resin composition causes a problem that ion exchange between ionic dyes increases foreign matters during frozen storage, leading to deterioration of storage stability. On the other hand, when n types of the components (d1a) are contained and organic ions contained in the photosensitive resin composition are of (n+1) types, the storage stability at the time of frozen storage is improved. This is presumed to be because the organic ion species for the component (d1a) was limited, thereby suppressing ion exchange between ionic dyes in the photosensitive resin composition.

As a first form in which n types of the components (d1a) are contained and the organic ions contained in the photosensitive resin composition satisfy (n+1) types, there is a case where the organic anion moieties or the organic cation moieties of the n types of the components (d1a) are all the same. For example, a case where n is 3 represents a case where the organic anion moieties or the organic cation moieties are all the same in the ionic dye 1, the ionic dye 2, and the ionic dye 3. In addition, in the case of n≥3, as the second form, there is a case where two or more types of organic anion moieties and two or more types of organic cation moieties of the n types of the components (d1a) are the same. For example, a case where n is 3 represents a case where the organic anion moieties of the ionic dye 1 and the ionic dye 2 are the same, and the organic cation moieties of the ionic dye 1 and the ionic dye 3 are the same. The first form is preferable from the viewpoint of suppressing ion exchange between ionic dyes and enhancing storage stability during frozen storage. From the viewpoint of enhancing the storage stability, n is preferably 2 to 5, more preferably 2 to 3, and still more preferably 2.

In the present invention, the pigment (d2) is preferably a pigment having high heat resistance and high light resistance from the viewpoint of discoloration at the time of curing or light irradiation. The component (d2-1) has a maximum absorption wavelength in a range of 490 nm or more and less than 580 nm at 300 to 800 nm, and thus examples thereof include a red pigment or a purple pigment. The component (d2-2) has a maximum absorption wavelength in a range of 580 nm or more and 800 nm or less at 300 to 800 nm, and examples thereof include blue pigments and green pigments.

Specific examples of the organic pigment are indicated by color index (C.I.) numbers. Examples of the component (d2-1) include red pigments such as Pigment Red 48:1, 122, 168, 177, 202, 206, 207, 209, 224, 242, and 254, and purple pigments such as Pigment Violet 19, 23, 29, 32, 33, 36, 37, and 38. Examples of the component (d2-2) include blue pigments such as Pigment Blue 15 (15:3, 15:4, 15:6, and the like), 21, 22, 60, and 64, and green pigments such as Pigment Green 7, 10, 36, 47, and 58. A pigment other than these pigments can also be contained.

In the present invention, an organic pigment used as the pigment (d2) may contain a pigment that is subjected to surface treatment such as rosin treatment, acidic group treatment, or basic group treatment if necessary. The organic pigment can be contained together with a dispersant in some cases. Examples of the dispersant can include cation-based, anion-based, nonionic, amphoteric, silicone-based, and fluorine-based surfactants.

The content of the component (d) is preferably 0.1 to 300 parts by mass, more preferably 0.2 to 200 parts by mass, and particularly preferably 1 to 200 parts by mass with respect to 100 parts by mass of the component (a). By setting the content of the component (d) to 0.1 parts by mass or more with respect to 100 parts by mass of the component (a), light having a corresponding wavelength can be absorbed. When the content is set to 300 parts by mass or less, light having a corresponding wavelength can be absorbed while maintaining the adhesion strength between the photosensitive colored resin film and the substrate, and the heat resistance and the mechanical characteristic of the heat-treated film.

In addition, the photosensitive resin composition of the present invention may contain a colorant other than the component (d). Containing the other colorant in addition to the component (d) can impart a light shielding property to shield light having a wavelength absorbed by the other colorant from light transmitted through the film of the photosensitive resin composition or light reflected from the film of the photosensitive resin composition. When the cured article of the present invention described below is used as a planarization layer and/or an insulating layer in an organic EL display device, if the light shielding property is imparted, it is possible to prevent deterioration, malfunction, leakage current, and the like due to intrusion of light into the TFT. Further, external light reflection from the wiring and the TFT can be suppressed, and the contrast between the light-emitting area and the non-light-emitting area can be improved.

### <Radically Polymerizable Compound>

The photosensitive resin composition of the present invention may include a radically polymerizable compound. In particular, when the photosensitive resin composition contains the photo initiator (e2), it is essential to contain a radically polymerizable compound. The term “radically polymerizable compound” refers to a compound having a plurality of ethylenic unsaturated double bonds in the molecule. At the time of exposure, radical polymerization of the radically polymerizable compound proceeds by radicals generated from the photo initiator (e2), and as a result, the portion irradiated with light is insolubilized, and thus, a negative pattern can be obtained. Further, containing the radically polymerizable compound promotes photocuring of the portion irradiated with light to allow to further improve the sensitivity. In addition, the crosslinking density after heat curing is improved, and thus the hardness of the cured article can be improved.

The radically polymerizable compound is preferably a compound in which radical polymerization is likely to proceed and a (meth)acrylic group is included. From the viewpoint of the improvement in sensitivity upon exposure to light and the improvement in the hardness of the cured article, a compound having two or more (meth)acrylic groups in the molecule is more preferable. The radically polymerizable compound preferably has a double bond equivalent of 80 to 400 g/mol from the viewpoint of improving the sensitivity at the time of exposure and improving the hardness of the cured article.

Examples of the radically polymerizable compound can include trimethylolpropane tri(meth)acrylate, ditrimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, 2,2-bis[4-(3-(meth)acryloxy-2-hydroxypropoxy)phenyl]propane, 1,3,5-tris((meth)acryloxyethyl)isocyanuric acid, 1,3-bis((meth)acryloxyethyl)isocyanuric acid, 9,9-bis[4-(2-(meth)acryloxyethoxy)phenyl]fluorene, 9,9-bis[4-(3-(meth)acryloxypropoxy)phenyl]fluorene, and 9,9-bis(4-(meth)acryloxyphenyl)fluorene, and acid modified products, ethylene oxide modified products, and propylene oxide modified products of the above-described compounds.

The content of the radically polymerizable compound is preferably 15 parts by mass or more, and more preferably 30 parts by mass or more, with respect to total 100 parts by mass of the component (a) and the radically polymerizable compound, from the viewpoint of further improving the sensitivity and reducing the taper angle. On the other hand, from the viewpoint of further improving the heat resistance of the cured article and reducing the taper angle, 65 parts by mass or less are preferable, and 50 parts by mass or less are more preferable, with respect to 100 parts by mass of the total of the component (a) and the radically polymerizable compound.

### <Thermal Cross-Linking Agent>

The photosensitive resin composition of the present invention may contain a thermal cross-linking agent other than the component (c). The term “thermal cross-linking agent” refers to a compound having at least two thermally reactive functional groups such as an alkoxymethyl group, a methylol group, an epoxy group, and an oxetanyl group in the molecule. Containing the thermal cross-linking agent can cause crosslink between the thermal cross-linking agent and the component (a) or between the thermal cross-linking agents to improve the heat resistance, chemical resistance, and bending resistance of the cured article after thermal curing. From the viewpoint of reducing the transmittance at 300 nm to 500 nm after curing, the thermal cross-linking agent is preferably a compound having low reactivity with a phenolic hydroxyl group, and is preferably an alkoxymethyl group. This is presumed to be because, in the crosslinked body made of the component (b) and the component (c), when the phenolic hydroxyl group of the component (b) reacts with the thermal cross-linking agent, the crosslinked body is less likely to have a quinone structure.

Preferable specific examples of the compound having at least two alkoxymethyl groups or methylol groups can include DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA and HMOM-TPHAP (product names, manufactured by Honshu Kagaku Industry Co., Ltd.), and “NIKALAC” (a registered trademark) MX-290, “NIKALAC” MX-280, “NIKALAC” MX-270, and “NIKALAC” MX-279 (product names, manufactured by Sanwa Chemical Co., Ltd.).

Preferable examples of the compound having at least two epoxy groups can include “EPOLIGHT” (registered trademark) 40E, “EPOLIGHT” 100E, “EPOLIGHT” 200E, “EPOLIGHT” 400E, “EPOLIGHT” 70P, “EPOLIGHT” 200P, “EPOLIGHT” 400P, “EPOLIGHT” 1500NP, “EPOLIGHT” 80MF, “EPOLIGHT” 4000, and “EPOLIGHT” 3002 (all manufactured by Kyoeisha Chemical Co., Ltd.), “DENACOL” (registered trademark) EX-212L, “DENACOL” EX-214L, “DENACOL” EX-216L, and “DENACOL” EX-850L (all manufactured by Nagase ChemteX Corporation), GAN and GOT (all manufactured by Nippon Kayaku Co., Ltd.), “EPIKOTE” (registered trademark) 828, “EPIKOTE” 1002, “EPIKOTE” 1750, “EPIKOTE” 1007, YX8100-BH30, E1256, E4250, and E4275 (all manufactured by Japan Epoxy Resin Co., Ltd.), “EPICLON” (registered trademark) EXA-9583 and HP4032 (all manufactured by DIC Corporation), VG3101 (manufactured by Mitsui Chemicals, Inc.), “TEPIC” (registered trademark) S, “TEPIC” G, and “TEPIC” P (all manufactured by Nissan Chemical Industries, Ltd.), “DENACOL” EX-321L (manufactured by Nagase ChemteX Corporation), NC6000 (manufactured by Nippon Kayaku Co., Ltd.), “Epotohto” (registered trademark) YH-434L (manufactured by Tohto Kasei Co., Ltd.), EPPN502H and NC3000 (manufactured by Nippon Kayaku Co., Ltd.), and “EPICLON” (registered trademark) N695 and HP7200 (all manufactured by DIC Corporation).

Examples of the compound having at least two oxetanyl groups can include ETERNACOLL EHO, ETERNACOLL OXBP, ETERNACOLL OXTP, and ETERNACOLL OXMA (all manufactured by Ube Industries, Ltd.), and oxetanized phenol novolac.

Two or more of the thermal cross-linking agents may be contained in combination.

The content of the thermal cross-linking agent is preferably 1 part by mass or more and 30 parts by mass or less in 100 parts by mass of the total amount of the photosensitive resin composition excluding the solvent. If the content of the thermal cross-linking agent is 1 part by mass or more in 100 parts by mass of the total amount of the photosensitive resin composition excluding the solvent, the chemical resistance of the cured article can be further enhanced. In addition, if the content of the thermal cross-linking agent is 30 parts by mass or less in 100 parts by mass of the total amount of the photosensitive resin composition excluding the solvent, the photosensitive resin composition is excellent in storage stability.

### <Solvent>

The photosensitive resin composition of the present invention may contain a solvent. Containing the solvent can cause the photosensitive resin composition to be in a varnish state and the coating property can be improved.

Examples of the solvent may include polar aprotic solvents such as γ-butyrolactone, ethers such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, tripropylene glycol monoethyl ether, tetrahydrofuran, and dioxane, ketones such as acetone, methyl ethyl ketone, diisobutyl ketone, cyclohexanone, 2-heptanone, 3-heptanone, and diacetone alcohol, esters such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, and ethyl lactate, other esters such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, i-propyl acetate, n-butyl acetate, i-butyl acetate, n-pentyl formate, i-pentyl acetate, n-butyl propionate, ethyl butyrate, n-propyl butyrate, i-propyl butyrate, n-butyl butyrate, methyl pyruvate, ethyl pyruvate, n-propyl pyruvate, methyl acetoacetate, ethyl acetoacetate, and ethyl 2-oxobutanoate, aromatic hydrocarbons such as toluene and xylene, amides such as N-methylpyrrolidone, N,N-dimethylformamide, N,N-dimethylacetamide, 3-methoxy-N,N-dimethylpropionamide, 3-butoxy-N,N-dimethylpropionamide, N,N-dimethylpropanamide, and N,N-dimethylisobutylamide, and 3-methyl-2-oxazolidinone. Two or more types of these solvents may be contained.

The content of the solvent is not particularly limited but is preferably 100 to 3000 parts by mass and more preferably 150 to 2000 parts by mass with respect to 100 parts by mass of the total amount of the photosensitive resin composition excluding the solvent. In 100 parts by mass of the total amount of the solvent, the proportion of a solvent having a boiling point of 180° C. or more is preferably 20 parts by mass or less, and more preferably 10 parts by mass or less. Setting the proportion of the solvent having a boiling point of 180° C. or more to 20 parts by mass or less can further reduce the amount of outgas after heat curing and further enhance the long-term reliability of an organic EL apparatus.

### <Adhesion Promoter>

The photosensitive resin composition of the present invention may contain an adhesion promoter. Specific examples of the adhesion promoter can include: a silane coupling agent such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane and N-phenyl-3-aminopropyltrimethoxysilane; a titanium chelating agent; an aluminum chelating agent; and a compound produced by reacting an aromatic amine compound with a silicon compound containing an alkoxy group. Two or more of these adhesion promoters may be contained. Containing these adhesion promoters can enhance the development adhesion, in development or the like, of a resin film with a base substrate such as a silicon wafer, indium tin oxide (ITO), SiO₂, or silicon nitride. In this case, it becomes also possible to improve the resistance to oxygen plasma that is used for washing purposes or a UV ozone treatment. The content of the adhesion promoter is preferably 0.01 to 10 parts by mass with respect to 100 parts by mass of the total amount of the photosensitive resin composition excluding the solvent.

### <Surfactant>

The photosensitive resin composition of the present invention may contain an adhesion promoter, and wettability with a substrate can be improved. Examples of the surfactant can include fluorine-based surfactants such as SH series, SD series, and ST series manufactured by Toray Dow Corning, BYK series manufactured by BYK JAPAN K.K., KP series manufactured by Shin-Etsu Chemical Co., Ltd., DISFOAM series manufactured by NOF CORPORATION, “MEGAFACE (registered trademark)” series manufactured by DIC Corporation, Fluorad series manufactured by Sumitomo 3M Limited, “SURFLON (registered trademark)” series and “AsahiGuard (registered trademark)” series manufactured by Asahi Glass Co., Ltd., and POLYFOX series manufactured by OMNOVA Solutions Inc., and acryl-based and/or methacryl-based surfactants such as POLYFLOW series manufactured by Kyoeisha Chemical Co., Ltd. and “DISPARLON (registered trademark)” series manufactured by Kusumoto Chemicals, Ltd.

When the surfactant is included, the content is preferably 0.001 to 1 parts by mass with respect to 100 parts by mass of the total amount of the photosensitive resin composition excluding the solvent.

### <Inorganic Particles>

The photosensitive resin composition of the present invention may include an inorganic particle. Preferable specific examples of the inorganic particles can include silicon oxide, titanium oxide, barium titanate, alumina, and talc. The primary particle diameter of the inorganic particles is preferably 100 nm or less and more preferably 60 nm or less.

The content of the inorganic particles is preferably 5 to 90 parts by mass in 100 parts by mass of the total amount of the photosensitive resin composition excluding the solvent.

### <All Chlorine Atoms and all Bromine Atoms>

In the photosensitive resin composition of the present invention, the total mass of all chlorine atoms and all bromine atoms contained in the photosensitive resin composition is preferably 150 ppm or less, more preferably 100 ppm or less, and still more preferably less than 2 ppm, which is the lower detection limit of combustion ion chromatography, with respect to the total mass of solid contents excluding the solvent from the photosensitive resin composition.

Setting the total amount of all chlorine atoms and all bromine atoms contained in the photosensitive resin composition to 150 ppm or less with respect to the solid content of the photosensitive resin composition can suppress deterioration of an electrode or a light-emitting layer in an organic EL display device including the cured article obtained by curing the photosensitive resin composition, and can improve long-term reliability.

In addition, setting the total amount of all chlorine atoms and all bromine atoms contained in the photosensitive resin composition to 150 ppm or less with respect to the solid content obtained by excluding the solvent from the photosensitive resin composition can enhance the storage stability of the photosensitive resin composition of the present invention during frozen storage.

The total mass of all chlorine atoms and all bromine atoms contained in the photosensitive resin composition can be measured by, for example, combustion ion chromatography in which the photosensitive resin composition is burned at 900 to 1000° C. in a combustion tube of an analyzer, the generated gas is absorbed into a solution, and a part of the absorbent is analyzed by ion chromatography.

### <Method for Producing Photosensitive Resin Composition>

Then, a method for producing the photosensitive resin composition of the present invention will be described. For example, the photosensitive resin composition of the present invention can be obtained by dissolving the component (a), the component (b), the component (c), and the component (e), and if necessary, the component (d), a radically polymerizable compound, a thermal cross-linking agent, a solvent, an adhesion promoter, a surfactant, inorganic particles, and the like.

Examples of the dissolving method include stirring and heating. In the case of heating, the heating temperature is preferably set within a range without impairing the performance of the photosensitive resin composition, and typically to room temperature to 80° C. The order of dissolving the components is not particularly limited, and examples of the method include a method in which the compounds are dissolved in the order of ascending solubility. Components that are likely to generate bubbles at the time of stirring and dissolution, such as surfactants and some adhesion promoters, can be added last after dissolving other components to prevent poor dissolution of other components due to generation of bubbles.

The obtained photosensitive resin composition is preferably filtered using a filtration filter to remove dust and particles. The pore size of the filter is, for example, 0.5 μm, 0.2 μm, 0.1 μm, 0.07 μm, 0.05 μm, or 0.02 μm, but is not limited thereto. Examples of the material of the filtration filter include polypropylene (PP), polyethylene (PE), nylon (NY), and polytetrafluoroethylene (PTFE). Among the materials, polyethylene and nylon are preferable.

### <Method for Producing Cured Article>

The method for producing a cured article of the present invention is a method for producing a cured article, including the steps of forming a resin film made of the photosensitive resin composition of the present invention on a substrate, exposing the resin film, developing the exposed resin film, and subjecting the developed resin film to a heat treatment.

A step of forming a resin film made of the photosensitive resin composition of the present invention on a substrate will be described. In the present invention, the resin film can be obtained by applying the photosensitive resin composition of the present invention to obtain a coating film of the photosensitive resin composition, and drying the coating film.

As the substrate, a known substrate such as a glass substrate can be used.

Examples of the method of applying the photosensitive resin composition of the present invention include a spin coating method, a slit coating method, a dip coating method, a spray coating method, and a printing method. Among the methods, the slit coating method is preferable because a coating liquid can be applied in a small amount to be advantageous for cost reduction. The amount of the coating liquid to be used in the slit coating method is, for example, about ⅕ to 1/10 of that in the spin coating method. As the slit nozzle used for application, slit nozzles put on the market from a plurality of manufacturers can be selected. Examples of the slit nozzle include “Linear Coater” manufactured by Dainippon Screen Mfg. Co., Ltd., “Spinless” manufactured by TOKYO OHKA KOGYO CO., LTD., “TSCoater” manufactured by Toray Engineering Co., Ltd., “Table Coater” manufactured by CHUGAI RO CO., LTD., “CS Series” and “CL Series” manufactured by Tokyo Electron Ltd., “In-line type slit coater” manufactured by CERMATRONICS BOEKI Co., Ltd., and “Head Coater HC series” manufactured by Hirata Corporation. The application speed is generally in the range of 10 mm/sec to 400 mm/sec. The coating film is usually formed so that the thickness of the dried film is 0.1 to 10 μm, and preferably 0.3 to 5 μm although the film thickness depends on, for example, the solid content concentration and the viscosity of the photosensitive resin composition.

Prior to the application, the substrate to which the photosensitive resin composition is applied may be pretreated with the above-described adhesion promoter in advance. Examples of the method of pretreatment include a method in which the surface of the substrate is treated with a solution prepared by dissolving 0.5 to 20 mass % of the adhesion promoter in a solvent such as isopropanol, ethanol, methanol, water, tetrahydrofuran, propylene glycol monomethyl ether acetate, propylene glycol monomethyl ether, ethyl lactate, or diethyl adipate. Examples of the method of treating the surface of the substrate include a spin coating method, a slit die coating method, a bar coating method, a dip coating method, a spray coating method, and a steam treatment method.

After the application, vacuum drying treatment is performed if necessary.

The vacuum drying rate depends on the volume of the vacuum chamber, the capacity of the vacuum pump, the diameter of the pipe between the chamber and the pump, and the like, but, for example, is preferably set to a condition that the pressure in the vacuum chamber is reduced to 40 Pa after a lapse of 60 seconds in the absence of the coated substrate. The general vacuum drying time is often about 30 seconds to 100 seconds, and the ultimate pressure in the vacuum chamber at the end of vacuum drying is usually 100 Pa or less in the presence of the coated substrate. Setting the ultimate pressure to 100 Pa or less can bring the coating film into a dry state in which stickiness of the surface of the coating film is reduced, and as a result, it is possible to suppress surface contamination and generation of particles in the subsequent substrate conveyance.

After the application or vacuum drying, the coating film is generally heated and dried. This step is also referred to as prebaking. For drying, a hot plate, an oven, an infrared ray, or the like is used. In the case of using a hot plate, the coating film is held and heated directly on the plate, or on a jig such as a proxy pin installed on the plate. The heating time is preferably 1 minute to several hours. The heating temperature depends on the type and the purpose of the coating film, but is preferably 80° C. or more, and more preferably 90° C. or more from the viewpoint of promoting solvent drying at the time of prebaking. From the viewpoint of reducing the progress of curing at the time of prebaking, the heating temperature is preferably 150° C. or less, and more preferably 140° C. or less.

Then, the step of exposing the resin film will be described.

The resin film of the present invention can form a pattern. For example, a desired pattern can be formed by irradiating the resin film with actinic rays through a photomask having the desired pattern for exposure and conducting development.

In the step of exposing the resin film, the photomask used for exposure is preferably a half-tone photomask having a light-transmitting portion, a light-shielding portion, and a semi-translucent portion. The exposure with the use of the half-tone photomask can form a pattern which has a step shape after development. When a positive resin film is used, in a pattern having a step shape, a portion formed from the light-shielding portion corresponds to a thick film portion, and a portion formed from a halftone exposed portion irradiated with active actinic rays through the semi-translucent portion corresponds to a thin film portion. When the transmittance of the light-transmitting portion in the half-tone photomask is taken as 100%, the transmittance of the semi-translucent portion is preferably 5% or more and more preferably 10% or more. When the transmittance of the semi-translucent portion is within the above range, a step difference between the thick film portion and the thin film portion can be clearly formed. The transmittance of the semi-translucent portion is preferably 30% or less, preferably 25% or less, still more preferably 20% or less, and most preferably 15% or less. When the transmittance of the semi-translucent portion is within the above range, the film thickness of the thin film portion can be increased, and the OD value of the entire film can be increased even when a black cured article having a low OD value in visible light per film thickness of 1 μm is formed.

Examples of the actinic rays used for exposure include ultraviolet rays, visible light, electron beams, and X-rays. In the present invention, i-line (365 nm), h-line (405 nm), and g-line (436 nm) of a mercury lamp are preferably used. When the resin film has positive photosensitivity, the exposed portion is dissolved in the developer. When the resin film has negative photosensitivity, the exposed portion is cured and insolubilized in the developer.

Then, the step of developing the exposed resin film will be described.

After the exposure, the exposed portion is removed in the case of the resin film having positive photosensitivity, and the unexposed portion is removed in the case of the resin film having negative photosensitivity with a developer to form a desired pattern. The developer is preferably an aqueous solution of a compound having alkaline properties, such as tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine and hexamethylenediamine. To the alkaline aqueous solution, one or more components may be added, and examples of the components include polar solvents such as N-methyl-2-pyrrolidone, N,N-dimethylformamide, N,N-dimethylacetamide, dimethylsulfoxide, γ-butyrolactone, and dimethylacrylamide, alcohols such as methanol, ethanol, and isopropanol, esters such as ethyl lactate and propylene glycol monomethyl ether acetate, and ketones such as cyclopentanone, cyclohexanone, isobutyl ketone, and methyl isobutyl ketone. Examples of the method of development include a spray method, a paddle method, an immersion method, and an ultrasonic method.

Then, the pattern formed by development is preferably rinsed with distilled water. The pattern may be rinsed with distilled water to which a component is added, and examples of the component include alcohols such as ethanol and isopropyl alcohol, and esters such as ethyl lactate and propylene glycol monomethyl ether acetate.

Then, the step of subjecting the developed resin film to heat treatment will be described.

After the development, the developed resin film is subjected to heat treatment to provide a cured article.

The heat treatment temperature is preferably 180° C. or more, more preferably 200° C. or more, still more preferably 230° C. or more, and particularly preferably 250° C. or more from the viewpoint of further reducing the amount of outgas generated from the cured article. From the viewpoint of improving the film toughness of the cured article, the temperature is preferably 500° C. or less, and more preferably 450° C. or less. In this temperature range, the temperature may be raised stepwise or may be continuously raised. The time for the heat treatment is preferably 30 minutes or more from the viewpoint of further decreasing the amount of outgas. The time for the heat treatment is preferably 3 hours or less from the viewpoint of improving the film toughness of the cured article. Examples thereof include a method for performing heat treatment at 150° C. and 250° C. for 30 minutes each, and a method for performing heat treatment while linearly increasing the temperature from room temperature to 300° C. over a period of 2 hours.

### <Cured Article>

A first aspect of the cured article of the present invention is a cured article (hereinafter, the cured article may be referred to as a cured article of the first aspect) obtained by curing the photosensitive resin composition of the present invention. Subjecting the photosensitive resin composition of the present invention to heat treatment can remove components exhibiting low heat resistance and thus further improve the heat resistance and chemical resistance. Particularly, when the photosensitive resin composition of the present invention contains a polyimide precursor, a polybenzoxazole precursor, a copolymer thereof, or a copolymer thereof with a polyimide, it is possible to further improve the heat resistance and chemical resistance since the imide ring and oxazole ring are formed by the heat treatment.

In addition, the component (b) and the component (c) are used in combination in the present invention, thereby allowing to reduce the ultraviolet light transmittance of the cured article. Further, using the component (b), the component (c), and the component (d) in combination in the present invention reduces the visible light transmittance of the cured article to allow to provide a black cured article. The heat treatment temperature is preferably 180° C. or more, more preferably 200° C. or more, still more preferably 230° C. or more, and particularly preferably 250° C. or more from the viewpoint of further reducing the amount of outgas generated from the cured article. From the viewpoint of improving the film toughness of the cured article, the temperature is preferably 500° C. or less, and more preferably 450° C. or less. In this temperature range, the temperature may be raised stepwise or may be continuously raised. The time for the heat treatment is preferably 30 minutes or more from the viewpoint of further decreasing the amount of outgas. The time for the heat treatment is preferably 3 hours or less from the viewpoint of improving the film toughness of the cured article. Examples thereof include a method in which the heat treatment is performed at 150° C. for 30 minutes and at 250° C. for 30 minutes and a method in which the heat treatment is performed while linearly raising the temperature from room temperature to 300° C. over 2 hours.

In addition, a second aspect of the cured article of the present invention is a cured article (hereinafter may be referred to as a cured article of the second aspect) containing a crosslinked body of 1,2,4-trihydroxybenzene or pyrogallol and a thermal cross-linking agent (c) having a partial structure represented by the formula (1).

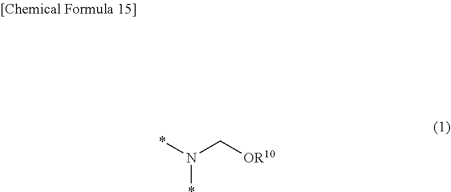

In the formula (1), R¹⁰ represents a hydrogen atom or an alkyl group. * each represents a bond, but a carbonyl group is not adjacent to a nitrogen atom.

The cured article contains a crosslinked body of 1,2,4-trihydroxybenzene or pyrogallol and the thermal cross-linking agent (c) having a partial structure represented by the formula (1), thereby allowing to reduce the transmittance of the cured article at a wavelength of 300 nm to 500 nm. From the viewpoint of further lowering the transmittance of 300 nm to 500 nm after curing, it is more preferable that the cured article contains a crosslinked body of 1,2,4-trihydroxybenzene and the thermal cross-linking agent (c) having a partial structure represented by the formula (1).

Specifically, the crosslinked body of 1,2,4-trihydroxybenzene or pyrogallol and the thermal cross-linking agent (c) having a partial structure represented by the formula (1) is a compound in which OR¹⁰ in the thermal cross-linking agent (c) having a partial structure represented by the formula (1) is desorbed by heat and crosslinked with an aromatic C—H bond in 1,2,4-trihydroxybenzene or pyrogallol via a methylene bond, and examples thereof include the following partial structure and a partial structure in which a quinone structure is formed by dehydrogenation from the following partial structure.

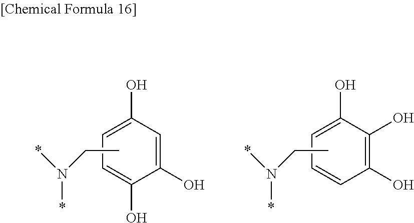

* each represents a bond, but a carbonyl group is not adjacent to a nitrogen atom.

When the thermal cross-linking agent (c) having a partial structure represented by the formula (1) has two or more partial structures represented by the formula (1) in the molecule, the thermal cross-linking agent (c) may form a crosslinked body with 1,2,4-trihydroxybenzene or pyrogallol in the molecule at at least one or more crosslinking points, and may form a crosslinked body with another compound at another crosslinking point.

The other suitable aspect of the thermal cross-linking agent (c) having a partial structure represented by the formula (1) in the cured article of the second aspect is the same as the thermal cross-linking agent (c) having a partial structure represented by the formula (1) described above.

Examples of the method for measuring whether the cured article contains a crosslinked body of 1,2,4-trihydroxybenzene or pyrogallol and the thermal cross-linking agent (c) having a partial structure represented by the formula (1) include a method in which components in the cured article are extracted with an organic solvent, and the extracted solution is measured by liquid ion chromatography, and a method in which components in the cured article are measured using time-of-flight secondary ion mass spectrometry.

In addition, the third aspect of the cured article of the present invention is a cured article formed on a support, wherein the cured article (hereinafter may be referred to as a cured article of the third aspect) has a normalized secondary ion intensity of ¹³⁷C₇H₅O₃⁻ of 1.0×10⁻⁴ or more as measured by time-of-flight secondary ion mass spectrometry under measurement conditions that cutting is performed by an Ar gas cluster ion beam method in a direction from a surface of the cured article toward the support, a primary ion species is Bi₃⁺⁺, a primary ion current is 0.1 pA, and an irradiation region of the primary ion is a region inside a quadrangle having a side length of 200 μm.

The normalized secondary ion intensity in the present invention is a secondary ion intensity obtained by normalizing the integrated intensity of ¹³⁷C₇H₅O₃⁻ ions by the total number of primary ions irradiated, and the total number of primary ions irradiated can be calculated by multiplying the number of primary ions irradiated per one time by the number of integrations per depth point and the number of depth points from the surface of the cured article to the support.

When the cured article of the third aspect is included in a planarization layer and/or a pixel defining layer of an organic EL display element described later, it is preferable to perform time-of-flight secondary ion mass spectrometry on a surface portion of the cured article in a region 2 μm or more away from a contact hole end portion or a pixel opening end portion in a planar direction. A region of 2 μm or less in the planar direction from the contact hole end portion or the pixel opening end portion overlaps the skirt of the cured article, and the film thickness from the surface of the cured article to the support becomes non-uniform in the analysis area, and the number of depth points may not be stable in the measurement area.

For example, when the time-of-flight secondary ion mass spectrometry is performed on the cured article provided in the organic EL display device, it is necessary to expose the surface of the cured article. Hereinafter, an example of a method for exposing the surface of the cured article will be described, but the exposure method is not limited to the following. In addition, when the support exists above and below the cured article, the time-of-flight secondary ion mass spectrometry may be performed in a state where the support interface between the cured article and either one of the supports is exposed.

As a method for exposing the surface of the cured article, for example, by using a sputtering gun such as argon, cesium, oxygen, or gallium, the upper portion of the surface of the intended cured article can be removed to expose the surface of the cured article. Alternatively, as an exposure method using chemical etching, the surface of the cured article can be exposed by a method in which both or one of the electrodes sandwiched between the upper and lower sides of the pixel defining layer is dissolved with an acid or an alkali to form a gap between the upper and lower sides of the cured article, and the laminated body is delaminated. Further, as an exposure method using the oblique cutting method, the cover glass of the organic EL display device is removed, and the exposed laminated body including the organic EL layer, the pixel defining layer, and the like is collectively cut obliquely with respect to the light extraction direction, whereby the surface of the cured article can be exposed.

The normalized secondary ion intensity of ¹³⁷C₇H₅O₃⁻ is 1.0×10⁻⁴ or more as measured by time-of-flight secondary ion mass spectrometry under measurement conditions that cutting is performed by an Ar gas cluster ion beam method in a direction from a surface of the cured article toward the support, a primary ion species is Bi₃⁺⁺, a primary ion current is 0.1 pA, and an irradiation region of the primary ion is a region inside a quadrangle having a side length of 200 μm, whereby the transmittance of the cured article at 300 nm to 500 nm can be reduced.

The cured article of the third aspect can be obtained, for example, by heat-treating a resin film on a support made of a composition containing the component (a), trihydroxybenzene, and the thermal cross-linking agent (c) having a partial structure represented by the formula (1). This is presumed to be because the crosslinked body of trihydroxybenzene and the thermal cross-linking agent (c) having a partial structure represented by the formula (1) is dehydrogenated to form a quinone structure, thereby increasing the concentration of ¹³⁷C₇H₅O₃⁻ as a fragment ion in the cured article.

The normalized secondary ion intensity of ¹³⁷C₇H₅O₃⁻ in the cured article of the third aspect is 1.0×10⁻⁴ or more, and from the viewpoint of further reducing the transmittance of the cured article at 300 nm to 500 nm, preferably 2.0×10⁻⁴ or more, and more preferably 3.0×10⁻⁴ or more. The upper limit of the normalized secondary ion intensity of ¹³⁷C₇H₅O₃⁻ in the cured article is not particularly limited, but is preferably 1.0×10⁻² or less.

Examples of the trihydroxybenzene include 1,2,4-trihydroxybenzene, pyrogallol, and phloroglucinol, and from the viewpoint of further lowering the transmittance of the cured article at 300 nm to 500 nm, 1,2,4-trihydroxybenzene and pyrogallol are preferable, and 1,2,4-trihydroxybenzene is more preferable. The other suitable aspect of the thermal cross-linking agent (c) having a partial structure represented by the formula (1) in the cured article of the third aspect is the same as the thermal cross-linking agent (c) having a partial structure represented by the formula (1) described above.

### <Application Examples of Photosensitive Resin Composition and Cured Article>

The photosensitive resin composition and the cured article of the present invention are suitably used in a surface protective layer and an interlayer insulating layer of a semiconductor element, an insulating layer of an organic electroluminescence (hereinafter referred to as EL) element, a planarization layer of a thin film transistor (hereinafter referred to as TFT) substrate to be used for driving a display device in which an organic EL element is used, a wiring protective insulating layer of a circuit substrate, an on-chip microlens of a solid-state imaging element, and planarization layers for various display devices and solid-state imaging elements. For example, the photosensitive resin composition and the cured article are suitable as a surface protective layer or an interlayer insulating layer in an MRAM having low heat resistance or in a promising next-generation memory such as a polymer memory (polymer ferroelectric RAM: PFRAM) or a phase change memory (phase change RAM: PCRAM or ovonics unified memory: OUM). The photosensitive resin composition and the cured article can also be used in an insulating layer in a display device including a first electrode formed on a substrate and a second electrode provided so as to face to the first electrode, such as a liquid crystal display (LCD), an electrochemical display (ECD), an electroluminescent display (ELD), or a display device in which an organic electroluminescent element is used (organic electroluminescent device). Hereinafter, an organic EL display device, a semiconductor device, and a semiconductor electronic component will be described as examples.

### <Organic EL Display Device>

The organic EL display device of the present invention includes a drive circuit, a planarization layer, a first electrode, an insulating layer, a light-emitting layer, and a second electrode that are placed over a substrate, in which the planarization layer and/or the insulating layer includes the cured article of the present invention.

When the planarization layer and/or the insulating layer includes the cured article of the present invention, the transmittance of the planarization layer and/or the insulating layer at a wavelength of 450 nm is preferably less than 30%. If the transmittance at a wavelength of 450 nm is less than 30%, in the organic EL display device using the oxide semiconductor layer TFT, it is possible to prevent malfunction or the like due to entry of ultraviolet light into the TFT. In order to prevent ultraviolet light from entering the TFT, the transmittance at a wavelength of 450 nm is preferably less than 30%, more preferably less than 20%, and still more preferably less than 10%. The lower limit of the transmittance at a wavelength of 450 nm is not particularly limited, but is 0.01% or more.

In addition, when the planarization layer and/or the insulating layer includes the cured article of the present invention, the OD value (optical density) of the planarization layer and/or the insulating layer in visible light per 1 μm of film thickness is preferably 0.5 to 1.5. If the OD value is 0.5 or more, the light shielding property can be improved by the cured article, and thus in display devices such as organic EL display devices or liquid crystal display devices, it becomes possible to reduce external light reflection, allowing to improve contrast in image display. From the viewpoint of reducing reflection, the OD value is preferably 0.5 or more, more preferably 0.6 or more, still more preferably 0.7 or more, particularly preferably 0.8 or more. If the OD value is 1.5 or less, the sensitivity upon exposure to light can be improved when a photosensitive resin composition containing a photosensitive compound is formed. From the viewpoint of high sensitivity, the OD value is 1.5 or less, more preferably 1.0 or less.

When the insulating layer is a black film, the film thickness of the insulating layer is preferably 1.0 to 5.0 μm, more preferably 1.5 μm or more, and still more preferably 2.0 μm or more. Setting the black insulating layer within the above range, even in a black film having a low OD value in visible light per film thickness of 1 μm, the OD value of the entire film can be increased, and the effect of reducing external light reflection can be enhanced.

Taking an active matrix display device as an example, an active matrix display device includes a TFT and a wiring located on a side portion of the TFT and connected to the TFT that are provided on a substrate such as glass or a plastic, a planarization layer provided on the TFT and the wiring so as to cover the unevenness, and a display element provided on the planarization layer. The display element and the wiring are connected via a contact hole formed in the planarization layer. An organic EL display device is particularly preferable in which the substrate having a drive circuit includes a resin film because flexible organic EL display device are recently the mainstream. When the cured article obtained by curing the photosensitive resin composition of the present invention is used as an insulating layer or a planarization layer in such a flexible display device, the cured article is particularly preferably used because bending resistance is excellent. The resin film is particularly preferably a polyimide from the viewpoint of improving the adhesion to a cured article obtained by curing the photosensitive resin composition of the present invention.

The organic EL display device preferably further includes a color filter having a black matrix in order to enhance the effect of reducing external light reflection. The black matrix preferably contains, for example, a resin such as an epoxy-based resin, an acrylic resin, a urethane-based resin, a polyester-based resin, a polyimide-based resin, a polyolefin-based resin, or a siloxane-based resin.

The black matrix contains a colorant. Examples of the colorant can be contained include black organic pigments, mixed color organic pigments, and inorganic pigments. Examples of the black organic pigments can be contained include carbon black, perylene black aniline black, and benzofuranone-based pigments. Examples of the mixed color organic pigments can be contained include pigments produced by mixing two or more pigments of a color of red, blue, green, purple, yellow, magenta, and/or cyan to make a pseudo black color. Examples of the black inorganic pigments can be contained include graphite; fine particles of metals such as titanium, copper, iron, manganese, cobalt, chromium, nickel, zinc, calcium, and silver; metal oxides; metal composite oxides, metal sulfides, metal nitrides; metal oxynitrides; and metal carbides. Among them, carbon black, titanium nitride, and titanium carbide having high light shielding property, and composite particles of these and a metal such as silver are preferable.

The OD value of the black matrix is preferably 1.5 or more, more preferably 2.5 or more, and still more preferably 4.5 or more.

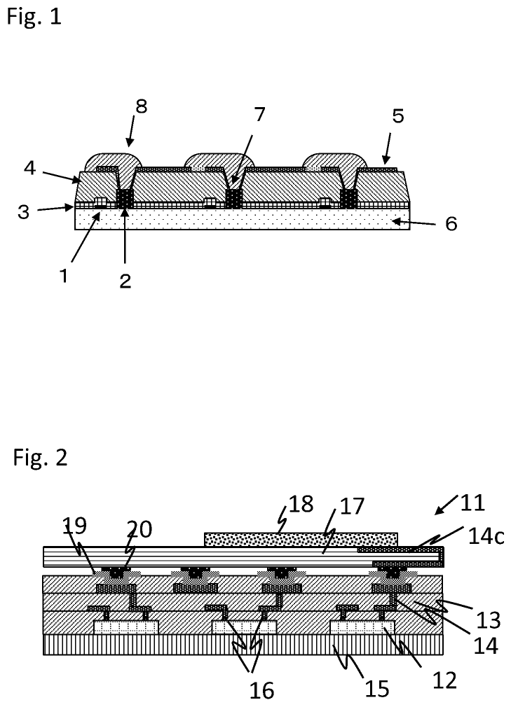

FIG. 1 is a cross-sectional view of an example of an organic EL display device. On a substrate 6, bottom-gate or top-gate thin film transistors (TFTs) 1 are provided in a matrix, and a TFT insulating layer 3 is formed in a state of covering the TFTs 1. On the TFT insulating layer 3, a wiring 2 connected to the TFTs 1 is provided. On the TFT insulating layer 3, a planarization layer 4 is further provided in a state that the wiring 2 is embedded in the planarization layer 4. The planarization layer 4 is provided with contact holes 7 reaching the wiring 2. ITOs (transparent electrodes) 5 are formed on the planarization layer 4 in a state that ITOs 5 are connected to the wiring 2 via the contact holes 7, respectively. Herein, each ITO 5 serves as an electrode of a display element (such as an organic EL element). Then, insulating layers 8 are formed so that the insulating layers 8 cover the peripheral edges of the ITOs 5, respectively. The organic EL element may be a top-emission organic EL device that emits light from the side opposite from the substrate 6, or may be a bottom-emission organic EL device that takes out light from the substrate 6 side. In this way, an active matrix organic EL display device is obtained in which each TFT 1 is connected to an organic EL element in order to drive the organic EL element.

The TFT insulating layer 3, the planarization layer 4 and/or the insulating layer 8 can be formed through the steps of forming a resin film made of the photosensitive resin composition of the present invention as described above, exposing the resin film, developing the exposed resin film, and subjecting the developed resin film to heat treatment. An organic EL display device can be obtained by a production method including these steps.

<Display Device Other than Organic EL Display Device>

A display device of the present invention other than the organic EL display device includes at least a metal wiring, the cured article of the present invention, and a plurality of luminescent elements, in which each of the luminescent elements includes a pair of electrode terminals on either one surface, the pair of electrode terminals are connected to a plurality of the metal wirings extending in the cured article, and the plurality of the metal wirings are configured to retain electrical insulation properties by the cured article.

The display device will be described with FIG. 2 as an example of one aspect.

In FIG. 2, a display device 11 includes a plurality of luminescent elements 12 disposed on a counter substrate 15 and a cured article 13 disposed on the luminescent elements 12. The phrase “on the luminescent element” may be not only “on the surface of the luminescent element” but also “on the upper side of the support substrate or the luminescent element”. In the aspect shown in FIG. 2, a configuration is exemplified in which a plurality of cured articles 13 are further laminated on the cured article 13 placed so as to be in contact with at least a part of the luminescent element 12 and a total of three layers are laminated, but the cured article 13 may be a single layer. The luminescent element 12 includes a pair of electrode terminals 16 on a surface opposite to a surface in contact with the counter substrate 15, and each electrode terminal 16 is connected to the metal wiring 14 extending in the cured article 13. If a plurality of metal wirings 14 extending in the cured article 13 are covered with the cured article 13, since the cured article 13 also functions as an insulating layer, the metal wirings are configured to retain electrical insulating properties. The fact that the metal wiring is configured to retain electrical insulating properties means that a portion requiring electrical insulating properties of the metal wiring is covered with a cured article obtained by curing the photosensitive resin composition containing the alkali-soluble resin (a). In the present invention, the state that the insulating layer has electrical insulating properties means a state that the volume resistivity of the insulating layer is 10¹² Ω·cm or more. The luminescent element 12 is electrically connected to a drive element 18 added to a luminescent element driving substrate 17 provided at a position facing the counter substrate 15 through the metal wirings 14 and 14c, and light emission of the luminescent element 12 can be controlled. The luminescent element driving substrate 17 is electrically connected to the metal wiring 14 via, for example, a solder bump 20. In order to prevent diffusion of metal such as the metal wiring 14, a barrier metal 19 may be disposed.

It is preferable that the cured article 13 is preferably black and has an OD value of 0.5 to 1.5 in visible light per film thickness of 1 μm of the insulating layer. If the OD value is 0.5 or more, the light shielding property can be improved by the cured article, and thus in display devices such as organic EL display devices or liquid crystal display devices, it becomes possible to reduce visualization of electrode wirings or reduce external light reflection, allowing to improve contrast in image display. If the OD value is 1.5 or less, the sensitivity upon exposure to light can be improved when a photosensitive resin composition containing a photosensitive compound is formed.

### EXAMPLES

Hereinafter, the present invention will be described with reference to Examples and the like, but the present invention is not limited to these Examples. Each evaluation in Examples was performed with the following method.

### (1) Evaluation of Sensitivity

The varnish obtained in each of Examples and Comparative Examples was applied onto an 8-inch silicon wafer with a spin coating method using a coating/development apparatus ACT-8 (manufactured by Tokyo Electron Ltd.), and the resulting product was baked at 120° C. for 2 minutes to prepare a prebaked film having a film thickness of 4.0 μm. The film thickness was measured using a stylus profiler (P-15, manufactured by KLA Corporation). Then, the prebaked film was exposed at exposure energy increased by 5 mJ/cm² in the range of 50 to 500 mJ/cm² through a mask having a pattern of a 10 μm hole using an exposure machine i-line stepper NSR-2005i9C (manufactured by Nikon Corporation). After the exposure, the exposed prebaked film was developed with the development apparatus of ACT-8 using a 2.38 mass % tetramethylammonium aqueous solution (hereinafter referred to as TMAH, manufactured by TAMA CHEMICAL CO., LTD.) as a developer until the amount of film loss reached 0.5 μm, then rinsed with distilled water, and shaken off and dried to obtain a pattern.

The obtained pattern was observed using an FPD microscope MX 61 (manufactured by Olympus Corporation) at a magnification of 20, and the aperture diameter of the hole was measured. The minimum exposure energy at which the aperture diameter of the contact hole reached 10 μm was determined and regarded as the sensitivity. It was determined as “A” when the sensitivity was less than 90 mJ/cm², “B” when 90 mJ/cm² or more and less than 120 mJ/cm², and “C” when 120 mJ/m² or more.

### (2) Evaluation of Ultraviolet Light Shielding Property (Transmittance at 450 nm)

The varnish obtained in each of Examples and Comparative Examples was applied onto a glass substrate of 5 centimeter square by spin coating so that the film thickness after the heat treatment (curing) was 2.0 μm, and prebaked at 120° C. for 120 seconds to prepare a prebaked film. Thereafter, using a high-temperature clean oven INH-9CD-S manufactured by Koyo Thermo Systems Co., Ltd., curing was performed at 250° C. for 60 minutes under a nitrogen atmosphere or an air atmosphere to prepare a cured film. The film thickness of the cured film was measured using a stylus profiler (P-15, manufactured by KLA Corporation). For the cured film thus obtained, the transmission spectrum at a wavelength of 300 nm to 800 nm was measured using an ultraviolet-visible spectrophotometer MultiSpec-1500 (manufactured by Shimadzu Corporation), and the transmittance at a wavelength of 450 nm at a film thickness of 2.0 μm after curing was determined. It was determined as “S” when the transmittance at a wavelength of 450 nm at a film thickness of 2.0 μm after curing was less than 10%, “A” when 10% or more and less than 20%, “B” when 20% or more and less than 30%, and “C” when 30% or more.

### (3) Evaluation of Visible Light Shielding Property (OD Value Per 1 μm, Transmittance at 450 nm)

For a cured film obtained in the same manner as in (2), the OD value was measured using an optical densitometer (361T, manufactured by X-Rite, Inc.), the transmission spectrum at a wavelength of 300 nm to 800 nm was measured using an ultraviolet-visible spectrophotometer MultiSpec-1500 (manufactured by Shimadzu Corporation), and the transmittance at a wavelength of 450 nm at a film thickness of 2.0 μm after curing was determined. The obtained OD value was divided by the film thickness of the cured film to provide an OD value per 1 μm (OD value per 1 μm=OD value/the film thickness of the cured film).

It was determined as “S” when the OD value per 1 μm was 0.70 or more and the transmittance at a wavelength of 450 nm was less than 10%,
“A” when the OD value per 1 μm was 0.70 or more and the transmittance at a wavelength of 450 nm was 10% or more and less than 20%,
“B” when the OD value per 1 μm was 0.70 or more and the transmittance at a wavelength of 450 nm was 20% or more and less than 30%,
“C” when the OD value per 1 μm was 0.70 or more and the transmittance at a wavelength of 450 nm was 30% or more,
“A” when the OD value per 1 μm was less than 0.70 and 0.50 or more and the transmittance at a wavelength of 450 nm was less than 10%,
“B” when the OD value per 1 μm was less than 0.70 and 0.50 or more and the transmittance at a wavelength of 450 nm was 10% or more and less than 20%, 1“C” when the OD value per 1 μm was less than 0.70 and 0.50 or more and the transmittance at a wavelength of 450 nm was 20% or more, and
“C” when the OD value per 1 μm was less than 0.50 regardless of the transmittance at a wavelength of 450 nm.

### (4) Chemical Resistance

After measuring the film thickness of the cured film obtained in the same manner as in (2), the cured film was immersed in a mixed solution of N-methylformamide/ethylene glycol=55/45 (weight ratio) at 60° C. for 3 minutes. The cured film taken out from the mixed solution was washed with pure water, then baked at 100° C. for 1 minute, and dehydrated. The film thickness was measured again, and the absolute value of the film thickness change amount before and after immersion in the solution was calculated. It was determined as “A” when the absolute value of the film thickness change amount was less than 0.3 μm, “B” when 0.3 μm or more and less than 0.8 μm, and “C” when 0.8 μm or more.

### (5) Evaluation of Change Amount of OD Value by Repeated Curing

For a cured film obtained in the same manner as in (2), the OD value was measured using an optical densitometer (361T, manufactured by X-Rite, Inc.), and the obtained OD value was divided by the film thickness of the cured film to determine the OD value per 1 μm after curing once (OD value per 1 μm=OD value/film thickness of cured film). Subsequently, the same cured film was cured again at 250° C. for 60 minutes in a nitrogen atmosphere using a high-temperature clean oven INH-9CD-S manufactured by Koyo Thermo Systems Co., Ltd., and a cured film after curing twice was prepared. The film thickness and the OD value of the cured film were measured in the same manner, and the obtained OD value was divided by the film thickness of the cured film to calculate the OD value per 1 μm after curing twice. The absolute value of the difference between the OD value per 1 μm after curing once and the OD value per 1 μm after curing twice was determined as the change amount of the OD value by repeated curing, and it was determined as “A” when the change amount of the OD value by repeated curing was less than 0.05, “B” when less than 0.15 and 0.05 or more, and “C” when 0.15 or more.

### (6) Evaluation of Frozen Storage Stability

Using a coating and developing apparatus “CLEAN TRACK ACT-12” manufactured by Tokyo Electron Ltd., each varnish filtered and then stored in a freezer at −18° C. for 60 days was applied onto a 12-inch Si wafer and dried on a hot plate at 100° C. for 3 minutes to provide a photosensitive resin film having a film thickness of 1000 nm. For the obtained photosensitive resin film, the number of foreign matters having a size of 0.27 μm or more was measured with a wafer surface inspection apparatus “WM-10” manufactured by Topcon Corporation. The measurement area was an area of about 201 cm² inside a circle having a radius of 8 cm from the center of the wafer, and the number of foreign matters (defect density) per 1 cm² of the coating film was determined. It was determined as “A” when the defect density per one substrate was less than 1.00/cm², “B” when 1.00/cm² or more and less than 3.00/cm², and “C” when 3.00/cm² or more.

### Synthesis Example 1: Synthesis of Hydroxyl Group-Containing Diamine Compound (α)

2,2-bis(3-amino-4-hydroxypheny)hexafluoropropane (hereinafter, referred to as BAHF) (18.3 g (0.05 mol)) was dissolved in 100 mL of acetone and 17.4 g (0.3 mol) of propylene oxide and cooled to −15° C. A solution prepared by dissolving 3-nitrobenzoyl chloride (20.4 g (0.11 mol)) in acetone (100 mL) was added dropwise to the cooled solution. After completion of dropping, reaction was performed at −15° C. for 4 hours, and then the temperature was returned to room temperature. The precipitated white solid was separated by filtration and vacuum-dried at 50° C.

The solid material (30 g) was placed in a 300-mL stainless autoclave and then dispersed in methyl cellosolve (250 mL), and 5 mass % palladium-carbon (2 g) was added thereto. Hydrogen was introduced thereinto with a balloon, and a reduction reaction was performed at room temperature. After about 2 hours, it was confirmed that the balloon did not deflate anymore, and the reaction was terminated. After the termination of the reaction, a palladium compound as a catalyst was removed by filtration, and concentrating was performed using a rotary evaporator, thereby providing a hydroxyl group-containing diamine compound (c) represented by the following formula.

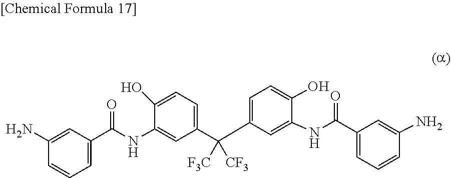 [SMILES: Nc1cccc(C(=O)Nc2cc(C(c3ccc(O)c(NC(=O)c4cccc(N)c4)c3)(C(F)(F)F)C(F)(F)F)ccc2O)c1]

### Synthesis Example 2: Synthesis of Quinone Diazide Compound (e-1)

Under a dried nitrogen stream, TrisP-PA (a product name, manufactured by Honshu Kagaku Industry Co., Ltd.) (21.22 g (0.05 mol)) and 5-naphthoquinone diazide sulfonic acid chloride (26.87 g (0.10 mol)) were dissolved in 1,4-dioxane (450 g) at room temperature. To this solution was added dropwise a mixture of 1,4-dioxane (50 g) and triethylamine (15.18 g) while avoiding the increase in temperature of the inside of the system to 35° C. or more. After the dropwise addition, the resultant mixture was stirred at 30° C. for 2 hours. A triethylamine salt was filtered out from the solution, and a filtrate was introduced into water. Subsequently, precipitates were collected by filtration. This precipitate was dried in a vacuum drier to obtain a quinone diazide compound (e-1) represented by the following formula.

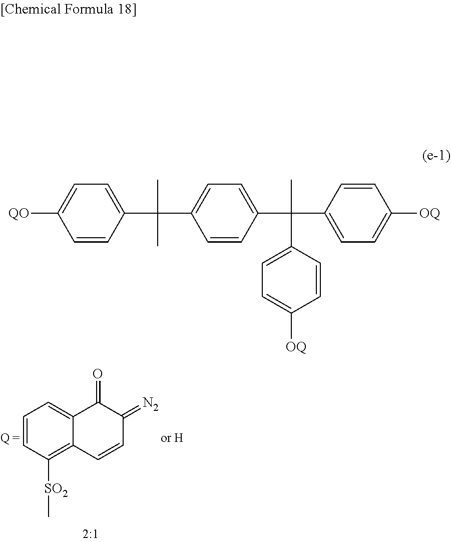

### Synthesis Example 3: Synthesis of Alkali-Soluble Resin (a-1)

Under a stream of dry nitrogen, 31.0 g (0.10 mol) of 3,3′,4,4′-diphenyl ether tetracarboxylic dianhydride (hereinafter, referred to as ODPA) was dissolved in 500 g of N-methylpyrrolidone (hereinafter, referred to as NMP). The hydroxyl group-containing diamine compound (a) (45.35 g (0.075 mol)) produced in Synthesis Example 1 and 1,3-bis(3-aminopropyl)tetramethyldisiloxane (hereinafter, referred to as SiDA) (1.24 g (0.005 mol)) were added together with NMP (50 g) to the solution, and the resultant mixture was reacted at 40° C. for 2 hours. Subsequently, 3-aminophenol (hereinafter, referred to as MAP) (4.36 g (0.04 mol)) that served as an end-capping agent was added together with NMP (5 g) to the reaction solution, and the resultant mixture was reacted at 50° C. for 2 hours. Then, a solution prepared by diluting 32.39 g (0.22 mol) of N,N-dimethylformamide diethyl acetal with 50 g of NMP was added. After the addition, the solution was stirred at 50° C. for 3 hours. After the completion of the stirring, the solution was cooled to room temperature and the solution was introduced into water (3 L) to produce white precipitates. This precipitate was collected by filtration, washed with water three times, and then dried in a vacuum dryer at 80° C. for 24 hours, thereby obtaining polyimide precursor (a-1) which was an alkali-soluble resin.

### Synthesis Example 4: Production of Ionic Dye d1-2-2

A mixture of 18.46 g (0.05 mol) of the compound represented by (β-1) in the following reaction formula, 120 g of sulfolane, 13.63 g of zinc chloride, and 20.58 g (0.15 mol) of 4-ethoxyaniline was heated and stirred at 170° C. for 8 hours. After completion of the reaction, the reaction solution was allowed to cool to room temperature, and the reaction solution was added dropwise to 450 g of 17.5 mass % hydrochloric acid at 0 to 10° C., followed by stirring for 1 hour. Subsequently, the precipitate was collected by filtration and added to 500 g of a 5 mass % sodium carbonate aqueous solution, and the mixture was stirred for 1 hour, collected by filtration, washed with pure water, and dried at 60° C. for 24 hours to obtain a xanthene compound (R-2) in which two nitrogen atoms were substituted with an aryl group.

Then, a mixture of 22.83 g (0.04 mol) of the obtained compound (β-2), 150 g of 1-methyl-2-pyrrolidone, 1.3 g of copper powder, 8.3 g of potassium carbonate, and 19.84 g (0.08 mol) of 4-iodophenetole was heated and stirred at 150° C. for 12 hours. After completion of the reaction, the reaction solution was filtered to remove insoluble matters, and the reaction solution was added dropwise to 450 g of 17.5 mass % hydrochloric acid at 0 to 10° C., followed by stirring for 1 hour. Thereafter, the precipitate was collected by filtration and dried at 60° C. for 24 hours to obtain a xanthene compound (β-3) in which four nitrogen atoms were substituted with an aryl group.

Then, to a mixture of 8.10 g (0.01 mol) of the obtained compound (β-3), 2.54 g (0.015 mol) of diphenylamine, 10.11 g (0.1 mol) of triethylamine, and 150 g of 1,2-dichloroethane, 1.69 g (0.011 mol) of phosphorus oxychloride was added dropwise at room temperature, and heated and stirred at 85° C. for 3 hours. After completion of the reaction, the reaction solution was allowed to cool to room temperature, and then the reaction solution was placed in 300 g of pure water, and extracted with 100 g of chloroform. The organic layer was washed with 150 g of 4 mol/L hydrochloric acid and 150 g of pure water, and then the solvent was distilled off to obtain a xanthene compound (β-4) in which the xanthene compound (β-3) was amidated.

Then, 9.98 g (0.01 mol) of the obtained compound (β-4) was dissolved in 150 g of N,N-dimethylformamide (DMF), 2.91 g (0.015 mol) of sodium p-toluenesulfonate was added thereto, and the mixture was heated and stirred at 40° C. for 3 hours. After the reaction solution was allowed to cool to room temperature, the reaction solution was poured into 1000 g of pure water, and precipitated crystals were collected by filtration, washed with water, and then dried at 60° C. for 24 hours to provide an ionic dye (d1-2-2) in which counter ions of (RB-4) were exchanged. The obtained compound was subjected to LC-MS analysis using a liquid chromatograph mass spectrometer (LC-MS2020 manufactured by Shimadzu Corporation), and was confirmed to be a target compound.

LC-MS (ESI, posi): m/z 963 [M+H]⁺

LC-MS (ESI, nega): m/z 171 [M]⁻.

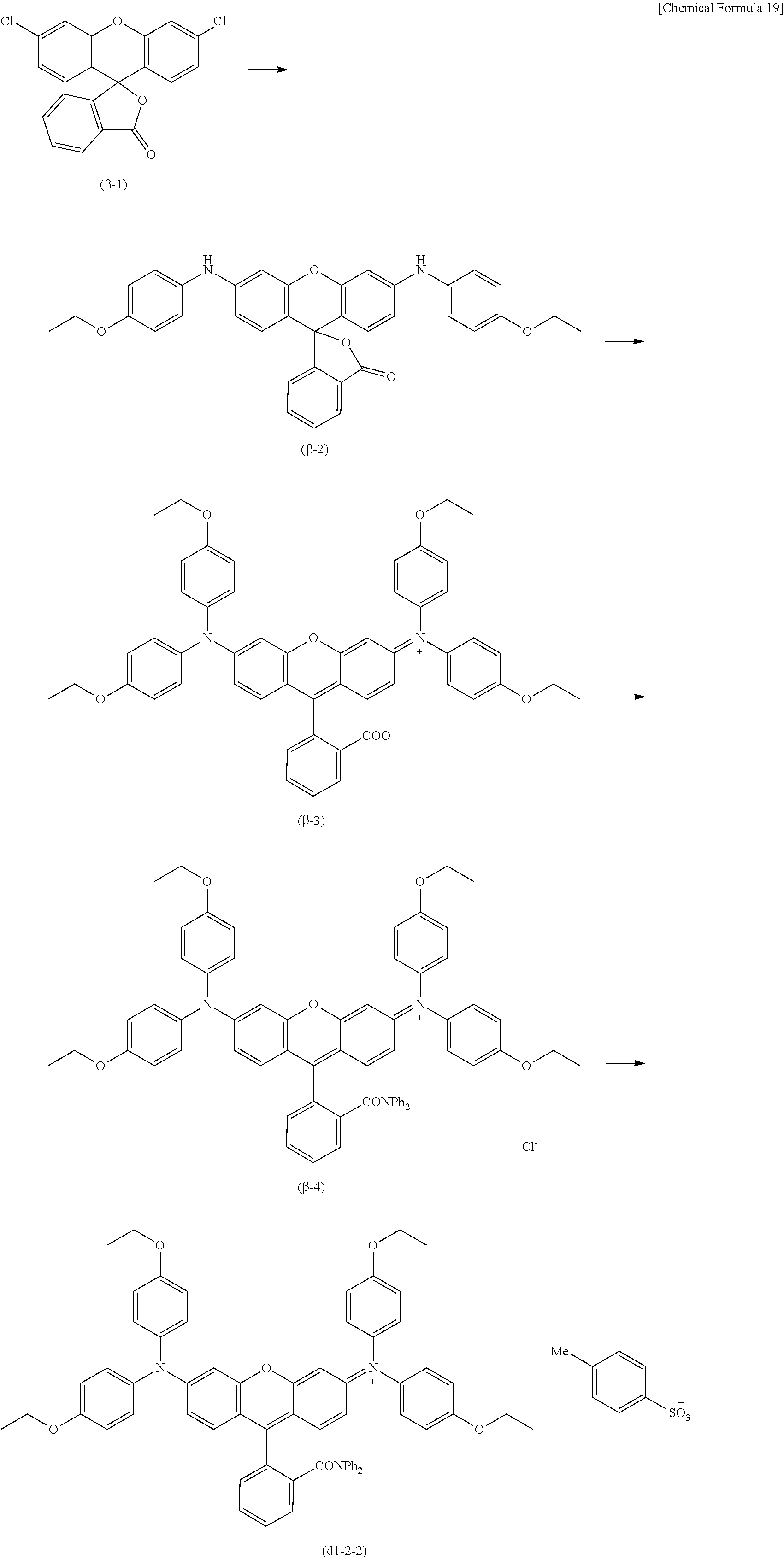

The names of the compounds used in each Examples and Comparative Examples are shown below. The ionic dye other than the commercially available product and the component (c) were synthesized using a known method. The maximum absorption wavelength and the ratio of the absorbance Abs₃₆₅ to absorbance Absₘₐₓ(Abs₃₆₅/Absₘₐₓ×100) of each colorant were calculated by measuring a transmission spectrum at a wavelength of 300 nm to 800 nm in a DMSO solution in which the concentration was adjusted such that the maximum value of absorbance was 1 or less using an ultraviolet-visible spectrophotometer MultiSpec-1500 (manufactured by Shimadzu Corporation). The results are shown in Table 1.
GBL: γ-butyrolactone
EL: Ethyl lactate
PGME: Propylene glycol monomethyl ether
b-1: Phloroglucinol
b1-1: Pyrogallol (an aromatic hydrocarbon (b) satisfying a condition that, with respect to any of the phenolic hydroxyl groups, at least one substitution position of other phenolic hydroxyl groups is an ortho position)
b12-1: 1,2.4-Trihydroxybenzene (an aromatic hydrocarbon (b) satisfying a condition that, with respect to any of the phenolic hydroxyl groups, at least one substitution position of other phenolic hydroxyl groups is an ortho position or a para position)
b′-1: 1,6-Dihydroxynaphthalene
b′-2: 4,4′,4″-Methylidyne trisphenol
b′-3: Hexahydroxybenzene
d1-1-1: C.I. Solvent Red 18
d1-2-1: C.I. Solvent Blue 45
d′-1: VALIFAST (registered trademark) BLACK 3830 (black dye defined by C.I. Solvent Black 34 (manufactured by Orient Chemical Industries Co., Ltd.))

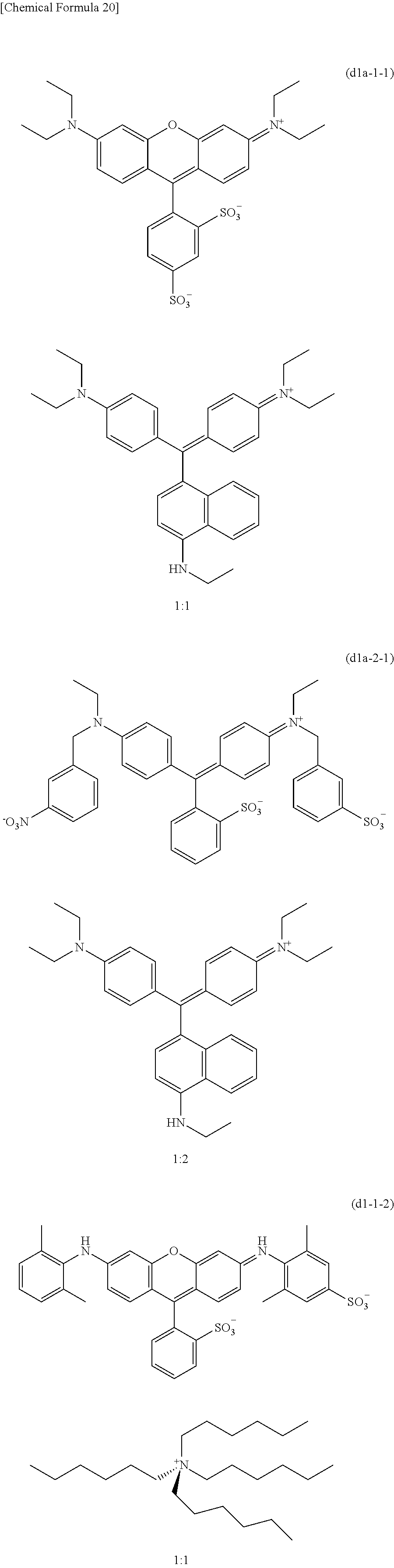

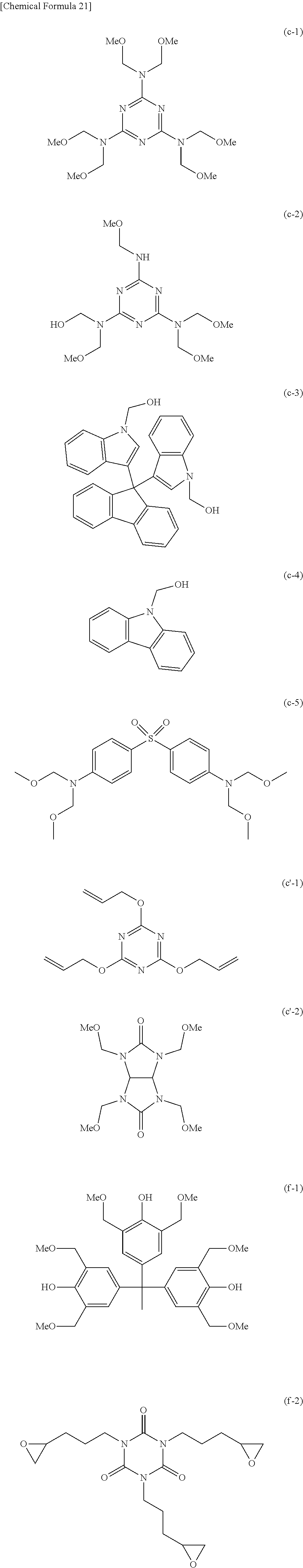

TABLE 1

| Colorant (d) | Maximum absorption wavelength | Abs₃₆₅/Absₘₐₓ |
|---|---|---|
| d1a-1-1 | 562 nm | 7.9% |
| d1a-2-1 | 629 nm | 7.0% |
| d1-1-1 | 508 nm | 18.8% |
| d1-1-2 | 532 nm | 6.1% |
| d1-2-1 | 625 nm | 20.9% |
| d1-2-2 | 622 nm | 12.3% |
| d′-1 | 576 nm | 89.4% |

### Example 1

10.0 g of the polyimide precursor (a-1), 2.0 g of the aromatic compound (b-1), 2.0 g of the triazine ring-containing compound (c-1), and 2.0 g of the photosensitive compound (e-1) were dissolved in a mixed solution of 10 g of GBL, 20 g of EL, and 70 g of PGME, and then the solution was filtered through a 0.2 μm polytetrafluoroethylene filter to provide a varnish AA of a positive photosensitive resin composition. Using the obtained varnish, the sensitivity, ultraviolet light shielding properties, and chemical resistance were evaluated as described above. However, for the evaluation of ultraviolet light shielding properties and chemical resistance, a cured film cured under a nitrogen atmosphere was used.

### Examples 2 and 3 and 5 to 12 and Comparative Examples 1 to 7

A varnish of the photosensitive resin composition was obtained in the same manner as in Example 1, except that the component (a), the component (b), the component (c), the component (e), other components, and the solvent were changed as shown in Tables 2 and 3. Using the obtained varnish, the sensitivity, ultraviolet light shielding properties, and chemical resistance were evaluated as described above. However, for the evaluation of ultraviolet light shielding properties and chemical resistance, a cured film cured under a nitrogen atmosphere was used.

### Example 4

Using the obtained varnish AC in Example 3, the sensitivity, ultraviolet light shielding properties, and chemical resistance were evaluated as described above. However, for the evaluation of ultraviolet light shielding properties and chemical resistance, a cured film cured under an air atmosphere was used.

### Example 13

10.0 g of the polyimide precursor (a-1), 2.0 g of the aromatic compound (b-1), 2.0 g of the thermal cross-linking agent (c-1), 1.0 g of the colorant (d1a-1-1), 0.8 g of the colorant (d1a-2-1), and 2.0 g of the photosensitive compound (e-1) were dissolved in a mixed solution of 10 g of GBL, 20 g of EL, and 70 g of PGME, and then the solution was filtered through a 0.2 μm polytetrafluoroethylene filter to provide a varnish BA of a positive photosensitive resin composition. Using the obtained varnish, the sensitivity, visible light shielding properties, and chemical resistance were evaluated as described above. However, for the evaluation of visible light shielding properties and chemical resistance, a cured film cured under a nitrogen atmosphere was used.

### Examples 14 to 25 and Comparative Examples 8 to 12

A varnish of the photosensitive resin composition was obtained in the same manner as in Example 12, except that the component (a), the component (b), the component (c), the component (d), the component (e), the thermal cross-linking agent, other components, and the solvent were changed as shown in Tables 4 and 5. Using the obtained varnish, the sensitivity, visible light shielding properties, and chemical resistance were evaluated as described above. However, for the evaluation of visible light shielding properties and chemical resistance, a cured film cured under a nitrogen atmosphere was used.

### Example 26

Using the varnish BC obtained in Example 15, the change amount of OD value and the frozen storage stability due to the repeated curing were evaluated as described above. However, for the evaluation of the change amount of OD value by repeated curing, a cured film cured under a nitrogen atmosphere was used.

### Example 27

The change amount of OD value and the frozen storage stability due to the repeated curing were evaluated in the same manner as in Example 26, except that the varnish BM obtained in Example 25 was used instead of the varnish BC obtained in Example 15. However, for the evaluation of the change amount of OD value by repeated curing, a cured film cured under a nitrogen atmosphere was used.

### Example 28

The cured film on a 5 centimeter square glass substrate made of the varnish AI obtained in Example 10 was subjected to extraction with 10 ml of tetrahydrofuran heated to 40° C., and LC-MS analysis was performed under the following conditions using the obtained extract.

LC System: UltiMate3000 (manufactured by Thermo Fisher Scientific Inc.)

MS System: Orbitrap Fusion (manufactured by Thermo Fisher Scientific Inc.)

Mobile phase: A 10 mmol/L Ammonium acetate aqueous solution
B Methanol/THF=1/1
Time program: 0→3 min
3→15 min
15→30 min
15→30 min

Flow rate: 0.5 ml/min

Ionization: Atmospheric pressure chemical ionization (APCI) method

MS detection: Scan (m/z 100 to 1500)

Column temperature: 45° C.

The analysis result confirmed a positive molecular ion at m/z 304.0968 (C₁₉H₁₄O₃N) and a negative molecular ion at m/z 302.0828 (C₁₉H₁₂O₃N). These were a positive ion and a negative ion of the molecule (C₁₉H₁₃O₃N) obtained by dehydrogenating the crosslinked body of the aromatic compound (b-1) and the thermal cross-linking agent (c-4) used in Example 10, and it was confirmed that the cured film contained a crosslinked product of 1,2,4-trihydroxybenzene and the component (c).

### Example 29

The normalized secondary ion intensity of ¹³⁷C₇H₅O₃⁻ in the cured article was measured by TOF-SIMS under the following conditions using the cured film made of the varnish AC obtained in Example 3 on a 5 centimeter square glass substrate. The normalized secondary ion intensity of ¹³⁷C₇H₅O₃⁻ was calculated by dividing the ¹³⁷C₇H₅O₃⁻ ion intensity by the total number of primary ions irradiated. The total number of primary ion irradiated is a value obtained by multiplying the number of primary ion irradiated per one time by the number of integration per depth point and the number of depth points from the surface of the cured article to the glass substrate.

Apparatus: “TOF.SIMS5” manufactured by ION-TOF Company

Ar cluster size (median): 1600

Primary ion: Bi₃⁺⁺

Primary ion acceleration voltage: 30 kV

Primary ion current: 0.1 pA

Time of one cycle of measurement: 140 μs

Number of scans: 1 scan/cycle measurement range: 200 μm×200 μm

Number of integrations per depth point: 256×256 times/point

Number of primary ions irradiated once: 43.7/time

As a result of the analysis, the number of points from the surface of the cured article to the glass substrate was 89, the integrated intensity of ¹³⁷C₇H₅O₃⁻ ions was 69327.09, and the normalized secondary ion intensity of ¹³⁷C₇H₅O₃⁻ in the cured article was 2.7×10⁻⁴.

### Comparative Example 13

The normalized secondary ion intensity of ¹³⁷C₇H₅O₃⁻ in the cured article was measured by TOF-SIMS in the same manner as in Example 29, except that the cured film made of the varnish XA obtained in Comparative Example 1 on a 5 centimeter square glass substrate was used instead of the varnish AC obtained in Example 3. As a result of the analysis, the number of points from the surface of the cured article to the glass substrate was 110, the integrated intensity of ¹³⁷C₇H₅O₃⁻ ions was 15821.09, and the normalized secondary ion intensity of ¹³⁷C₇H₅O₃⁻ in the cured article was 5.0×10⁻⁵.

Tables 2 to 6 show the compositions and evaluation results in Examples and Comparative Examples.

TABLE 2

| | | | Example | | Example | | Example | | Example | | Example | | Example | |
|---|---|---|---|---|---|---|---|---|---|---|---|---|---|---|
| | | | 1 | | 2 | | 3 | | 4 | | 5 | | 6 | |
| Composition | Resin composition | | AA | | AB | | AC | | AC | | AD | | AE | |
| | Component (a) | a-1 | 10.0 | g | 10.0 | g | 10.0 | g | 10.0 | g | 10.0 | g | 10.0 | g |
| | Component (b) | b-1 | 2.0 | g | | | | | | | | | | |
| | | b1-1 | | | 2.0 | g | | | | | | | | |
| | | b12-1 | | | | | 2.0 | g | 2.0 | g | 2.0 | g | 2.0 | g |
| | Component (c) | c-1 | 2.0 | g | 2.0 | g | 2.0 | g | 2.0 | g | 3.0 | g | 1.0 | g |
| | | c-2 | | | | | | | | | | | | |
| | | c-3 | | | | | | | | | | | | |
| | | c-4 | | | | | | | | | | | | |
| | | c-5 | | | | | | | | | | | | |
| | Component (e) | e-1 | 2.0 | g | 2.0 | g | 2.0 | g | 2.0 | g | 2.0 | g | 2.0 | g |
| | Other | b′-1 | | | | | | | | | | | | |
| | components | b′-2 | | | | | | | | | | | | |
| | | b′-3 | | | | | | | | | | | | |
| | | c′-1 | | | | | | | | | | | | |
| | | c′-2 | | | | | | | | | | | | |
| | Solvent | GBL | 10 | g | 10 | g | 10 | g | 10 | g | 10 | g | 10 | g |
| | | EL | 20 | g | 20 | g | 20 | g | 20 | g | 20 | g | 20 | g |
| | | PGME | 70 | g | 70 | g | 70 | g | 70 | g | 70 | g | 70 | g |

| Result | Curing atmosphere | | Nitrogen | Nitrogen | Nitrogen | Atmosphere | Nitrogen | Nitrogen |
|---|---|---|---|---|---|---|---|---|
| | Sensitivity | (mJ/cm²) | 70 | 70 | 70 | 70 | 70 | 70 |
| | | Evaluation | A | A | A | A | A | A |
| | Ultraviolet | Transmittance | 27 | 18 | 5 | 3 | 5 | 8 |
| | light shielding | at 450 nm (%) | | | | | | |
| | property | Evaluation | B | A | S | S | S | S |
| | Chemical | (μm) | 0.2 | 0.2 | 0.2 | 0.2 | 0.1 | 0.3 |
| | resistance | Evaluation | A | A | A | A | A | B |

| | | Example | Example | Example | Example | Example | Example |
|---|---|---|---|---|---|---|---|
| | | 7 | 8 | 9 | 10 | 11 | 12 |
| Composition | Resin composition | AF | AG | AH | AI | AJ | AK |

| | | | | | | | | | | | | | |
|---|---|---|---|---|---|---|---|---|---|---|---|---|---|
| Component (a) | a-1 | 10.0 | g | 10.0 | g | 10.0 | g | 10.0 | g | 10.0 | g | 10.0 | g |
| Component (b) | b-1 | | | | | | | | | | | | |
| | b1-1 | | | | | | | | | | | | |
| | b12-1 | 2.0 | g | 2.0 | g | 2.0 | | 2.0 | g | 2.0 | g | 2.0 | g |
| Component (c) | c-1 | | | | | | | | | | | | |
| | c-2 | 2.0 | g | | | | | | | | | | |
| | c-3 | | | 2.0 | g | 4.0 | g | | | | | | |
| | c-4 | | | | | | | 2.0 | g | 4.0 | g | | |
| | c-5 | | | | | | | | | | | 2.0 | g |
| Component (e) | e-1 | 2.0 | g | 2.0 | g | 2.0 | g | 2.0 | g | 2.0 | g | 2.0 | g |
| Other | b′-1 | | | | | | | | | | | | |
| components | b′-2 | | | | | | | | | | | | |
| | b′-3 | | | | | | | | | | | | |
| | c′-1 | | | | | | | | | | | | |
| | c′-2 | | | | | | | | | | | | |
| Solvent | GBL | 10 | g | 10 | g | 10 | g | 10 | g | 10 | g | 10 | g |
| | EL | 20 | g | 20 | g | 20 | g | 20 | g | 20 | g | 20 | g |
| | PGME | 70 | g | 70 | g | 70 | g | 70 | g | 70 | g | 70 | g |

| Result | Curing atmosphere | | Nitrogen | Nitrogen | Nitrogen | Nitrogen | Nitrogen | Nitrogen |
|---|---|---|---|---|---|---|---|---|
| | Sensitivity | (mJ/cm²) | 70 | 75 | 80 | 75 | 80 | 70 |
| | | Evaluation | A | A | A | A | A | A |
| | Ultraviolet | Transmittance | 7 | 11 | 6 | 17 | 8 | 10 |
| | light shielding | at 450 nm (%) | | | | | | |
| | property | Evaluation | S | A | S | A | S | A |
| | Chemical | (μm) | 0.2 | 0.4 | 0.3 | 0.6 | 0.3 | 0.3 |
| | resistance | Evaluation | A | B | B | B | B | B |

TABLE 3

| | | | Comparative | | Comparative | | Comparative | | Comparative | |
|---|---|---|---|---|---|---|---|---|---|---|
| | | | Example 1 | | Example 2 | | Example 3 | | Example 4 | |
| Composition | Resin composition | | XA | | XB | | XC | | XD | |
| | Component (a) | a-1 | 10.0 | g | 10.0 | g | 10.0 | g | 10.0 | g |
| | Component (b) | b-1 | | | | | | | | |
| | | b1-1 | | | | | | | | |
| | | b12-1 | | | 2.0 | g | | | | |
| | Component (c) | c-1 | 2.0 | g | | | 2.0 | g | 2.0 | g |
| | | c-2 | | | | | | | | |
| | | c-3 | | | | | | | | |
| | | c-4 | | | | | | | | |
| | | c-5 | | | | | | | | |
| | Component (e) | e-1 | 2.0 | g | 2.0 | g | 2.0 | g | 2.0 | g |
| | Other | b′-1 | | | | | 2.0 | g | | |
| | components | b′-2 | | | | | | | 2.0 | g |
| | | b′-3 | | | | | | | | |
| | | c′-1 | | | | | | | | |
| | | c′-2 | | | | | | | | |
| | Solvent | GBL | 10 | g | 10 | g | 10 | g | 10 | g |
| | | EL | 20 | g | 20 | g | 20 | g | 20 | g |
| | | PGME | 70 | g | 70 | g | 70 | g | 70 | g |

| Result | Curing atmosphere | | Nitrogen | Nitrogen | Nitrogen | Nitrogen |
|---|---|---|---|---|---|---|
| | Sensitivity | (mJ/cm²) | 100 | 70 | 80 | 80 |
| | | Evaluation | B | A | A | A |
| | Ultraviolet | Transmittance | 92 | 91 | 37 | 85 |
| | light shielding | at 450 nm (%) | | | | |
| | property | Evaluation | C | C | C | C |
| | Chemical | (μm) | 0.0 | 0.8 | 0.1 | 0.1 |
| | resistance | Evaluation | A | C | A | A |

| | | | Comparative | | Comparative | | Comparative | |
|---|---|---|---|---|---|---|---|---|
| | | | Example 5 | | Example 6 | | Example 7 | |
| Composition | Resin composition | | XE | | XF | | XG | |
| | Component (a) | a-1 | 10.0 | g | 10.0 | g | 10.0 | g |
| | Component (b) | b-1 | | | | | | |
| | | b1-1 | | | | | | |
| | | b12-1 | | | 2.0 | g | 2.0 | g |
| | Component (c) | c-1 | 2.0 | g | | | | |
| | | c-2 | | | | | | |
| | | c-3 | | | | | | |
| | | c-4 | | | | | | |
| | | c-5 | | | | | | |
| | Component (e) | e-1 | 2.0 | g | 2.0 | g | 2.0 | g |
| | Other | b′-1 | | | | | | |
| | components | b′-2 | | | | | | |
| | | b′-3 | 2.0 | g | | | | |
| | | c′-1 | | | 2.0 | g | | |
| | | c′-2 | | | | | 2.0 | g |
| | Solvent | GBL | 10 | g | 10 | g | 10 | g |
| | | EL | 20 | g | 20 | g | 20 | g |
| | | PGME | 70 | g | 70 | g | 70 | g |

| Result | Curing atmosphere | | Nitrogen | Nitrogen | Nitrogen |
|---|---|---|---|---|---|
| | Sensitivity | (mJ/cm²) | 70 | 70 | 70 |
| | | Evaluation | A | A | A |
| | Ultraviolet | Transmittance | 80 | 95 | 58 |
| | light shielding | at 450 nm (%) | | | |
| | property | Evaluation | C | C | C |
| | Chemical | (μm) | 0.7 | 0.6 | 0.1 |
| | resistance | Evaluation | B | B | A |

TABLE 4

| | | | Example | | Example | | Example | | Example | | Example | | Example | | Example | |
|---|---|---|---|---|---|---|---|---|---|---|---|---|---|---|---|---|
| | | | 13 | | 14 | | 15 | | 16 | | 17 | | 18 | | 19 | |
| Composition | Resin composition | | BA | | BB | | BC | | BD | | BE | | BF | | BG | |
| | Component (a) | a-1 | 10.0 | g | 10.0 | g | 10.0 | g | 10.0 | g | 10.0 | g | 10.0 | g | 10.0 | g |
| | Component (b) | b-1 | 2.0 | g | | | | | | | 3.0 | g | | | | |
| | | b1-1 | | | 2.0 | g | | | | | | | | | | |
| | | b12-1 | | | | | 2.0 | g | 1.0 | g | | | 2.0 | g | 2.0 | g |
| | Component (c) | c-1 | 2.0 | g | 2.0 | g | 2.0 | g | 2.0 | g | 2.0 | g | 2.0 | g | 2.0 | g |
| | | c-2 | | | | | | | | | | | | | | |
| | | c-3 | | | | | | | | | | | | | | |
| | | c-4 | | | | | | | | | | | | | | |
| | Component (d) | d1a-1-1 | 1.0 | g | 1.0 | g | 1.0 | g | 1.0 | g | 1.0 | g | 1.0 | g | 1.0 | g |
| | | d1a-2-1 | 0.8 | g | 0.8 | g | 0.8 | g | 0.8 | g | 0.8 | g | 0.8 | g | 0.8 | g |
| | | d1-1-1 | | | | | | | | | | | | | | |
| | | d1-1-2 | | | | | | | | | | | | | | |
| | | d1-2-1 | | | | | | | | | | | | | | |
| | | d1-2-2 | | | | | | | | | | | | | | |
| | Component (e) | e-1 | 2.0 | g | 2.0 | g | 2.0 | g | 2.0 | g | 2.0 | g | 2.0 | g | 2.0 | g |
| | Thermal cross- | f-1 | | | | | | | | | | | 1.0 | g | | |
| | linking agent | f-2 | | | | | | | | | | | | | 1.0 | g |
| | Other | b′-1 | | | | | | | | | | | | | | |
| | components | b′-2 | | | | | | | | | | | | | | |
| | | d′-1 | | | | | | | | | | | | | | |
| | Solvent | GBL | 10 | g | 10 | g | 10 | g | 10 | g | 10 | g | 10 | g | 10 | g |
| | | EL | 20 | g | 20 | g | 20 | g | 20 | g | 20 | g | 20 | g | 20 | g |
| | | PGME | 70 | g | 70 | g | 70 | g | 70 | g | 70 | g | 70 | g | 70 | g |

| Result | Curing atmosphere | | Nitrogen | Nitrogen | Nitrogen | Nitrogen | Nitrogen | Nitrogen | Nitrogen |
|---|---|---|---|---|---|---|---|---|---|
| | Sensitivity | (mJ/cm²) | 85 | 85 | 85 | 95 | 80 | 85 | 85 |
| | | Evaluation | A | A | A | B | A | A | A |
| | Visible light | OD value per 1 | 0.85 | 0.89 | 0.93 | 0.83 | 0.87 | 0.93 | 0.88 |
| | shielding | μm (/μm) | | | | | | | |
| | property | Transmittance | 21 | 11 | 4 | 22 | 14 | 4 | 12 |
| | | at 450 nm (%) | | | | | | | |
| | | Evaluation | B | A | S | B | A | S | A |
| | Chemical | (μm) | 0.3 | 0.3 | 0.3 | 0.2 | 0.6 | 0.0 | 0.1 |
| | resistance | Evaluation | B | B | B | A | B | A | A |

| | | | Example | | Example | | Example | | Example | | Example | | Example | |
|---|---|---|---|---|---|---|---|---|---|---|---|---|---|---|
| | | | 20 | | 21 | | 22 | | 23 | | 24 | | 25 | |
| Composition | Resin composition | | BH | | BI | | BJ | | BK | | BL | | BM | |
| | Component (a) | a-1 | 10.0 | g | 10.0 | g | 10.0 | g | 10.0 | g | 10.0 | g | 10.0 | g |
| | Component (b) | b-1 | | | | | | | | | | | | |
| | | b1-1 | | | | | | | | | | | | |
| | | b12-1 | 2.0 | g | 2.0 | g | 2.0 | g | 2.0 | g | 2.0 | g | 2.0 | g |
| | Component (c) | c-1 | 2.0 | g | 2.0 | g | | | | | | | 2.0 | g |
| | | c-2 | | | | | 2.0 | g | | | | | | |
| | | c-3 | | | | | | | 4.0 | g | | | | |
| | | c-4 | | | | | | | | | 4.0 | g | | |
| | Component (d) | d1a-1-1 | | | 1.0 | g | 1.0 | g | 1.0 | g | 1.0 | g | | |
| | | d1a-2-1 | 0.8 | g | | | 0.8 | g | 0.8 | g | 0.8 | g | | |
| | | d1-1-1 | 1.0 | g | | | | | | | | | | |
| | | d1-1-2 | | | | | | | | | | | 1.0 | g |
| | | d1-2-1 | | | 0.8 | g | | | | | | | | |
| | | d1-2-2 | | | | | | | | | | | 2.6 | g |
| | Component (e) | e-1 | 2.0 | g | 2.0 | g | 2.0 | g | 2.0 | g | 2.0 | g | 2.0 | g |
| | Thermal cross- | f-1 | | | | | | | | | | | | |
| | linking agent | f-2 | | | | | | | | | | | | |
| | Other | b′-1 | | | | | | | | | | | | |
| | components | b′-2 | | | | | | | | | | | | |
| | | d′-1 | | | | | | | | | | | | |
| | Solvent | GBL | 10 | g | 10 | g | 10 | g | 10 | g | 10 | g | 10 | g |
| | | EL | 20 | g | 20 | g | 20 | g | 20 | g | 20 | g | 20 | g |
| | | PGME | 70 | g | 70 | g | 70 | g | 70 | g | 70 | g | 70 | g |

| Result | Curing atmosphere | | Nitrogen | Nitrogen | Nitrogen | Nitrogen | Nitrogen | Nitrogen |
|---|---|---|---|---|---|---|---|---|
| | Sensitivity | (mJ/cm²) | 105 | 115 | 85 | 95 | 95 | 100 |
| | | Evaluation | B | B | B | B | B | B |
| | Visible light | OD value per 1 | 0.65 | 0.71 | 0.93 | 0.92 | 0.90 | 0.90 |
| | shielding | μm (/μm) | | | | | | |
| | property | Transmittance | 4 | 4 | 5 | 5 | 7 | 3 |
| | | at 450 nm (%) | | | | | | |
| | | Evaluation | A | S | S | S | S | S |
| | Chemical | (μm) | 0.3 | 0.3 | 0.3 | 0.4 | 0.5 | 0.3 |
| | resistance | Evaluation | B | B | B | B | B | B |

TABLE 5

| | | | Comparative | | Comparative | | Comparative | | Comparative | | Comparative | |
|---|---|---|---|---|---|---|---|---|---|---|---|---|
| | | | Example 8 | | Example 9 | | Example 10 | | Example 11 | | Example 12 | |
| Composition | Resin composition | | YA | | YB | | YC | | YD | | YE | |
| | Component (a) | a-1 | 10.0 | g | 10.0 | g | 10.0 | g | 10.0 | g | 10.0 | g |
| | Component (b) | b-1 | | | | | | | | | | |
| | | b1-1 | | | | | | | | | | |
| | | b12-1 | | | 2.0 | g | | | | | 2.0 | g |
| | Component (c) | c-1 | 2.0 | g | | | 2.0 | g | 2.0 | g | | |
| | | c-2 | | | | | | | | | | |
| | | c-3 | | | | | | | | | | |
| | | c-4 | | | | | | | | | | |
| | Component (d) | d1a-1-1 | 1.0 | g | 1.0 | g | 1.0 | g | 1.0 | g | | |
| | | d1a-2-1 | 0.8 | g | 0.8 | g | 0.8 | g | 0.8 | g | | |
| | | d1-1-1 | | | | | | | | | | |
| | | d1-1-2 | | | | | | | | | | |
| | | d1-2-1 | | | | | | | | | | |
| | | d1-2-2 | | | | | | | | | | |
| | Component (e) | e-1 | 2.0 | g | 2.0 | g | 2.0 | g | 2.0 | g | 2.0 | g |
| | Thermal cross- | f-1 | | | | | | | | | | |
| | linking agent | f-2 | | | | | | | | | | |
| | Other | b′-1 | | | | | 2.0 | g | | | | |
| | components | b′-2 | | | | | | | 2.0 | g | | |
| | | d′-1 | | | | | | | | | 4.0 | g |
| | Solvent | GBL | 10 | g | 10 | g | 10 | g | 10 | g | 10 | g |
| | | EL | 20 | g | 20 | g | 20 | g | 20 | g | 20 | g |
| | | PGME | 70 | g | 70 | g | 70 | g | 70 | g | 70 | g |

| Result | Curing atmosphere | | Nitrogen | Nitrogen | Nitrogen | Nitrogen | Nitrogen |
|---|---|---|---|---|---|---|---|
| | Sensitivity | (mJ/cm²) | 115 | 85 | 95 | 95 | 400 |
| | | Evaluation | B | A | B | B | C |
| | Visible light | OD value per 1 | 0.81 | 0.82 | 0.76 | 0.81 | 0.75 |
| | shielding | μm (/μm) | | | | | |
| | property | Transmittance | 60 | 58 | 33 | 52 | 13 |
| | | at 450 nm ( %) | | | | | |
| | | Evaluation | C | C | C | C | A |
| | Chemical | (μm) | 0.0 | 0.8 | 0.1 | 0.1 | 0.7 |
| | resistance | Evaluation | A | C | A | A | B |

TABLE 6

| | | OD value per | OD value per | Change amount of OD | | | | | |
|---|---|---|---|---|---|---|---|---|---|
| | | 1 μm after | 1 μm after | value by repeated curing | | Frozen storage stability | | | |
| | Resin | curing once | curing twice | Change | | Type of | Number of | (Number/ | |
| | composition | (/μm) | (/μm) | amount | Evaluation | ionic dye | organic ions | cm²) | Evaluation |
| Example 26 | BC | 0.93 | 0.82 | 0.11 | B | 2 | 1 | 0.02 | A |
| Example 27 | BM | 0.90 | 0.89 | 0.01 | A | 2 | 1 | 1.28 | B |

### DESCRIPTION OF REFERENCE SIGNS

1: TFT (thin film transistor)
2: Wiring
3: TFT insulating layer
4: Planarization layer
5: ITO (transparent electrode)
6: Substrate
7: Contact hole
8: Insulating layer
11: Display device
12: Luminescent element
13: Cured article
14, 14c: Metal wiring
15: Counter substrate
16: Electrode terminal
17: Luminescent element driving substrate
18: Drive element
19: Barrier metal
20: Solder bump

1. A photosensitive resin composition comprising:
an alkali-soluble resin (a);
an aromatic hydrocarbon (b) having at least one aromatic C—H bond and at least three phenolic hydroxyl groups in one aromatic ring;
a thermal cross-linking agent (c) having a partial structure represented by a formula (1); and
a photosensitive compound (e), 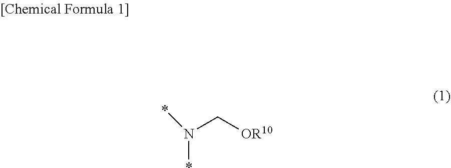
where R¹⁰ represents a hydrogen atom or an alkyl group, each * represents a bond, and a carbonyl group is not adjacent to a nitrogen atom.

2. The photosensitive resin composition according to claim 1, wherein the component (c) includes two or more partial structures represented by the formula (1) in a molecule.

3. The photosensitive resin composition according to claim 1, wherein the component (c) contains a triazine ring-containing compound (c1) represented by a formula (2): 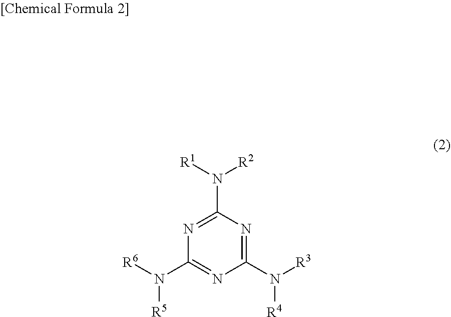
where R¹ to R⁶ each independently represent a hydrogen atom, an alkyl group having 1 to 10 carbon atoms, an alkenyl group having 2 to 10 carbon atoms, an alkenyl ether group having 2 to 10 carbon atoms, a methylol group, or an alkoxymethyl group, and at least one of R¹ to R⁶ is a methylol group or an alkoxymethyl group.

4. The photosensitive resin composition according to claim 1, further comprising a colorant (d) having a maximum absorption wavelength in any of a range of 490 nm or more and less than 800 nm at 300 to 800 nm, and having 0.1% or more and less than 60% of a ratio of absorbance Abs₃₆₅ at 365 nm to absorbance Absₘₐₓ at the maximum absorption wavelength in any of the range of 490 nm or more and less than 800 nm at 300 to 800 nm.

5. The photosensitive resin composition according to claim 4, wherein the component (d) contains a dye (d1-1) having a maximum absorption wavelength in any of a range of 490 nm or more and less than 580 nm at 300 to 800 nm and/or a dye (d1-2) having a maximum absorption wavelength in any of a range of 580 nm or more and less than 800 nm at 300 to 800 nm.

6. The photosensitive resin composition according to claim 4, wherein the component (d) contains an ionic dye forming an ion pair of an organic anion moiety and an organic cation moiety, and the organic anion moiety and the organic cation moiety is made of an organic anion moiety of an acidic dye and an organic cation moiety of a basic dye, respectively.

7. The photosensitive resin composition according to claim 4, comprising, as the component (d), n types of ionic dyes forming an ion pair of an organic anion moiety and an organic cation moiety,
wherein organic ions contained in the photosensitive resin composition are of (n+1) types, and
n represents an integer of 2 to 10.

8. The photosensitive resin composition according to claim 1, wherein in the component (b), with respect to any of the phenolic hydroxyl groups, at least one substitution position of other phenolic hydroxyl groups is an ortho position or a para position.

9. The photosensitive resin composition according to claim 1, wherein a content of the component (b) is 1 to 50 parts by mass with respect to 100 parts by mass of the component (a).

10. The photosensitive resin composition according to claim 1, wherein a content of the component (c) is 1 to 100 parts by mass with respect to 100 parts by mass of the component (a).

11. The photosensitive resin composition according to claim 1,
wherein the component (a) contains one or more types selected from the group consisting of a polyimide, a polyimide precursor, a polybenzoxazole, a polybenzoxazole precursor, a polyamideimide, a polyamideimide precursor, and a copolymer thereof.

12. The photosensitive resin composition according to claim 1, wherein a total mass of all chlorine atoms and all bromine atoms contained in the photosensitive resin composition is 150 ppm or less with respect to a total mass of solid content obtained by removing a solvent from the photosensitive resin composition.

13. A cured article obtained by curing the photosensitive resin composition according to claim 1.

14. An organic electroluminescence (EL) display device comprising:
a drive circuit; a planarization layer; a first electrode; an insulating layer; a light-emitting layer; and a second electrode that are placed over a substrate,
wherein the planarization layer and/or the insulating layer includes the cured article according to claim 13.

15. The organic EL display device according to claim 14, wherein the planarization layer and/or the insulating layer includes the cured article, and a transmittance of the planarization layer and/or the insulating layer at a wavelength of 450 nm is less than 30%.

16. The organic EL display device according to claim 14, wherein the planarization layer and/or the insulating layer includes the cured article, and an OD value of the planarization layer and/or the insulating layer per 1 μm of film thickness in visible light is 0.5 to 1.5.

17. The organic EL display device according to claim 14, further comprising a color filter having a black matrix.

18. A display device comprising: at least a metal wiring; the cured article according to claim 13; and a plurality of luminescent elements,
wherein each of the luminescent elements includes a pair of electrode terminals on either one surface, the pair of electrode terminals are connected to a plurality of the metal wirings extending in the cured article, and the plurality of the metal wirings are configured to retain electrical insulation properties by the cured article.

19. A cured article comprising a crosslinked body of 1,2,4-trihydroxybenzene or pyrogallol and a thermal cross-linking agent (c) having a partial structure represented by a formula (1): 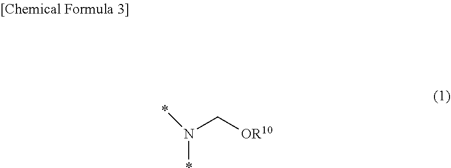
where R¹⁰ represents a hydrogen atom or an alkyl group, each * represents a bond, and a carbonyl group is not adjacent to a nitrogen atom.

20. A cured article formed on a support, wherein the cured article has a normalized secondary ion intensity of ¹³⁷C₇H₅O₃⁻ of 1.0×10⁻⁴ or more as measured by time-of-flight secondary ion mass spectrometry under measurement conditions that cutting is performed by an Ar gas cluster ion beam method in a direction from a surface of the cured article toward the support, a primary ion species is Bi₃⁺⁺, a primary ion current is 0.1 pA, and an irradiation region of the primary ion is a region inside a quadrangle having a side length of 200 μm.
